(19) United States
(12) Patent Application Publication
(10) Pub. No.: US 2018/0155511 A1
(43) Pub. Date: Jun. 7, 2018

(54) LAMINATE ROLL, OPTICAL UNIT, ORGANIC EL DISPLAY DEVICE, AND METHODS FOR MANUFACTURING TRANSPARENT ELECTRICALLY CONDUCTIVE FILM AND OPTICAL UNIT

(71) Applicant: NITTO DENKO CORPORATION, Ibaraki-shi, Osaka (JP)

(72) Inventors: Kentaro TAKEDA, Ibaraki-shi (JP); Naoki TSUNO, Ibaraki-shi (JP); Hidehiko ANDO, Ibaraki-shi (JP); Akinori NISHIMURA, Ibaraki-shi (JP); Takami HIKITA, Ibaraki-shi (JP)

(21) Appl. No.: 15/575,600

(22) PCT Filed: Apr. 14, 2016
(86) PCT No.: PCT/JP2016/062026

§ 371 Date: Nov. 20, 2017

(30) Foreign Application Priority Data
May 29, 2015 (JP) 2015-110402
Jan. 25, 2016 (JP) 2016-011550

(51) Int. Cl. C08J 5/18; G02B 5/30; H01L 51/52; B32B 27/32

(52) U.S. Cl. CPC C08J 5/18; G02B 5/3058; B32B 2307/42; H01L 51/5293; B32B 27/325; G02B 5/3083

(57) ABSTRACT

A laminate roll that is an elongated laminate wound in a form of a roll, wherein the laminate includes a transparent electrically conductive film including a polycycloolefin film and a transparent electrically conductive layer, and inclination of the direction of the slow axis of the polycycloolefin film with respect to the longitudinal direction of the elongated laminate falls within a range of±2° over the entire elongated laminate except opposite end portions thereof each of which accounts for 5% of the entire width of the elongated laminate.

### TECHNICAL FIELD

The present invention relates to a transparent electrically conductive film including a polycycloolefin film and a transparent electrically conductive layer and a method for manufacturing the transparent electrically conductive film, a roll of a laminate including the transparent electrically conductive film, an optical unit including the transparent electrically conductive film and a method for manufacturing the optical unit, and an organic EL display device including the optical unit.

### BACKGROUND ART

A transparent electrically conductive film formed of a polycycloolefin film as a base material has conventionally been known (Patent Literature 1). A polycycloolefin film is optically isotropic and is therefore suitable for use in combination with a film that controls the phase of light, such as a polarizing film and a retardation film.

On the other hand, an organic EL display device using a transparent electrically conductive film and integrated with a touch sensor has been known, as described, for example, in Patent Literature 2. In the known organic EL display device, a touch panel laminate 916 is provided on the visually recognized side of an organic EL display panel 901, and a polarizing function laminate 920 having a circularly polarizing function is provided on the visually recognized side of the touch panel laminate 916, as shown in FIG. 1. The polarizing function laminate 920 includes a polarizing film 921 and a retardation membrane 923, and the polarizing film 921 is provided on the visually recognized side of the retardation membrane 923. The touch panel laminate 916 has a structure in which a dielectric layer 915 and patterned electrodes 912-1 and 912-2, which are provided on opposite surfaces of the dielectric layer 915, are layered on each other. A window 902 is disposed on the visually recognized side of the polarizing function laminate 920.

In the organic EL display device, a typical example of the retardation membrane 923 is a quarter-wave retardation membrane. In this case, light incident through the visually recognized side of the organic EL display device is changed by the polarizing film 921 to linearly polarized light, and the linearly polarized light is converted by the quarter-wave retardation membrane into circularly polarized light. The light having entered the organic EL display device is internally reflected and changed to opposite-phase circularly polarized light, and the opposite-phase circularly polarized light is converted by the quarter-wave retardation membrane into linearly polarized light having a polarization direction perpendicular to the polarization direction of the incident linearly polarized light, so that the polarizing film 921 prevents the converted linearly polarized light from exiting through the visually recognized side thereof. In this configuration, it is conceivable to use an optically isotropic dielectric layer as the dielectric layer 915 to prevent a change in the phase of the light that passes through the dielectric layer 915, degradation in an internal reflection prevention function, and occurrence of a shift in hue. It is therefore conceivable to use an optically isotropic film, such as a polycycloolefin film, as the dielectric layer 915.

### CITATION LIST

### Patent Literature

Patent Literature 1: Japanese Patent Laid-Open No. 2014-229279

Patent Literature 2: Japanese Patent Laid-Open No. 2012-133312

### SUMMARY OF INVENTION

### Technical Problem

A polycycloolefin film is, however, not fully optically isotropic, but is slightly optically anisotropic. The amount of anisotropy of a polycycloolefin film is very small and has not been recognized as a problem. Degradation in viewability due to the slight anisotropy is, however, a problem in stringent requirements for viewability of recent display devices.

The present inventors have found the following phenomenon that has not been recognized before. That is, in a widthwise central portion of a raw-material polycycloolefin film, the direction of the slow axis is parallel to the MD direction, but the discrepancy between the direction of the slow axis and the MD direction increases with distance from the widthwise central portion toward end portions of the polycycloolefin film, and the in-plane retardation increases accordingly. That is, in the case where a raw-material polycycloolefin film is cut along the width direction into several films, the optical characteristics of the cut films undesirably vary. Further, when a cut film is has a large size, end portions of the cut film have degraded optical characteristics. Further, for example, in the known organic EL display device integrated with a touch sensor described above, degradation in viewability, such as a shift in hue, occurs. The present inventors have found the above problems that have not been recognized.

An object of the present invention is to suppress variation in the direction of the slow axis and in-plane retardation of a transparent electrically conductive film, and another object of the present invention is to suppress degradation in optical characteristics, such as a shift in hue, in an organic EL display device.

### Solution to Problem

An aspect of the present invention provides a laminate roll that is an elongated laminate wound in a form of a roll. The laminate includes a transparent electrically conductive film including a polycycloolefin film and a transparent electrically conductive layer, and inclination of a direction of a slow axis of the polycycloolefin film with respect to a longitudinal direction of the elongated laminate falls within a range of±2° over the entire elongated laminate except opposite end portions thereof each of which accounts for 5% of an entire width of the elongated laminate.

Another aspect of the present invention provides an optical unit including: a transparent electrically conductive film including a polycycloolefin film and a transparent electrically conductive layer; and a retardation film. A direction of a slow axis of the polycycloolefin film has an angular variation that falls within an angular range of 4°. In-plane retardation of the polycycloolefin film measured by using light having a wavelength of 550 nm at 23° C. ranges from 3 to 8 nm, and variation in the in-plane retardation falls within a range of 1.5 nm. In-plane retardation of the retardation film is so set as to cancel the in-plane retardation of the polycycloolefin film so that the retardation film and the transparent electrically conductive film as a whole have a desired in-plane retardation value.

In an embodiment of the present aspect, the retardation film may include a quarter-wave retardation membrane, and the desired value may be set at about a quarter of the wavelength.

In an embodiment of the present aspect, the retardation film may include a retardation membrane for angular viewing field compensation and a quarter-wave retardation membrane sequentially arranged from a side facing the transparent electrically conductive film, and the desired value can be set at about a quarter of the wavelength.

In these cases, inclination of a direction of a slow axis of the quarter-wave retardation membrane with respect to the direction of the slow axis of the polycycloolefin film may fall within a range of 0°±3°.

In these cases, inclination of a direction of a slow axis of the quarter-wave retardation membrane with respect to the direction of the slow axis of the polycycloolefin film may fall within a range of 90°±3°.

In an embodiment of the present aspect, the transparent electrically conductive layer may be made of indium tin oxide (ITO).

In an embodiment of the present aspect, the optical unit may further include a polarizing function laminate. The polarizing function laminate may include a polarizing film and the retardation film. The retardation film may be disposed on the transparent electrically conductive layer of the transparent electrically conductive film. The polarizing film may be disposed on a side opposite to the transparent electrically conductive film with respect to the retardation film.

In this case, the polarizing function laminate may have a function of producing circularly polarized light.

Another aspect of the present invention provides an organic EL display device including the optical unit described above and an organic EL display panel. The optical unit is disposed on a visually recognized side of the organic EL display panel, and the optical unit is further so disposed that the transparent electrically conductive film is located between the polarizing film and the organic EL display panel.

Still another aspect of the present invention provides a method for manufacturing a transparent electrically conductive film, the method including the steps of winding an elongated polycycloolefin film in a form of a roll and feeding the polycycloolefin film from the polycycloolefin film roll; carrying out a heating/winding process at a heating temperature ranging from 140 to 160° C. while winding the fed polycycloolefin film around a wind-up roll; and depositing a transparent electrically conductive layer on the polycycloolefin film having undergone the heating/winding process to produce a transparent electrically conductive film.

In an embodiment of the present aspect, the heating temperature may range from 145 to 155° C.

In this case, the heating temperature may range from 148 to 153° C.

Still another aspect of the present invention provides a method for manufacturing the optical unit described above, and the polarizing function laminate is bonded to the transparent electrically conductive film manufactured by using the manufacturing method described above to produce the optical unit.

### Advantageous Effect of Invention

The present invention can suppress variation in the direction of the slow axis and in-plane retardation of a transparent electrically conductive film and can further suppress degradation in optical characteristics, such as a shift in hue, in an organic EL display device.

Embodiments of a transparent electrically conductive film including a polycycloolefin film and a transparent electrically conductive layer and a method for manufacturing the transparent electrically conductive film, a roll of a laminate including the transparent electrically conductive film, an optical unit including the transparent electrically conductive film and a method for manufacturing the optical unit, and an organic EL display device including the optical unit according to the present invention will be described below in detail with reference to the drawings.

### BRIEF DESCRIPTION OF DRAWINGS

FIG. 1 is a cross-sectional view showing an organic EL display device of related art.

FIG. 2 is a cross-sectional view of a transparent electrically conductive film according to an embodiment of the present invention.

FIG. 3 is a partially enlarged view showing the configuration of a second curable resin layer in FIG. 2.

FIG. 4 is a cross-sectional view showing an organic EL display device according to an embodiment of the present invention.

FIG. 5 shows an example of change in front retardation along the width direction of a polycycloolefin film before and after a heating/winding process.

FIG. 6 shows an example of change in the direction of the slow axis along the width direction of the polycycloolefin film before and after the heating/winding process.

FIG. 7 shows the hue of light reflected off an optical unit in Examples and Comparative Examples.

FIG. 8 shows results of measurement of reflectance in Examples A10, A11 and Comparative Example A5, A6.

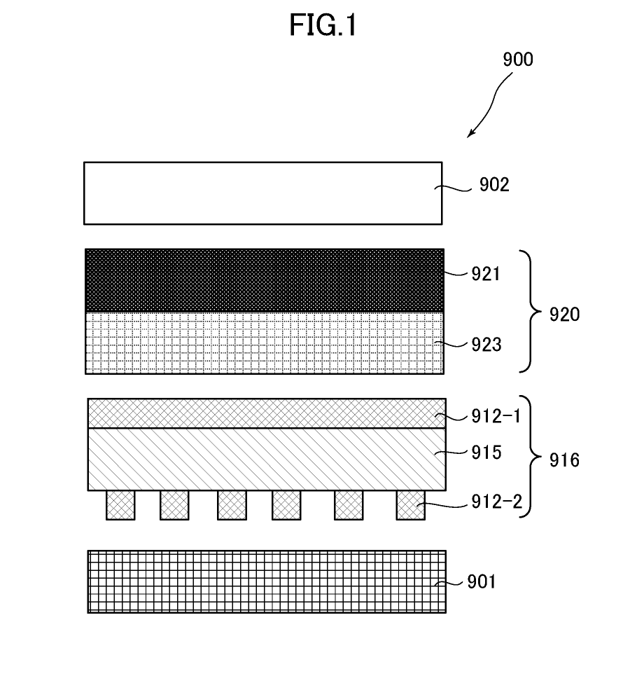

### DESCRIPTION OF EMBODIMENT

### Laminate Roll

A laminate roll according to the present invention is a laminate roll that is an elongated laminate wound in the form of a roll.

A laminate used to form the laminate roll according to the present invention includes a transparent electrically conductive film.

The transparent electrically conductive film used to form the laminate roll according to the present invention includes a polycycloolefin film and a transparent electrically conductive layer.

Inclination of the direction of the slow axis of the polycycloolefin film used to form the laminate roll according to the present invention with respect to the longitudinal direction of the elongated laminate falls within a range of±2°, preferably±1.5° over the entire elongated laminate except opposite end portions thereof each of which accounts for 5% of the entire width of the elongated laminate.

### Optical Unit

An optical unit according to the present invention includes the following two films: the transparent electrically conductive film including the polycycloolefin film and the transparent electrically conductive layer; and a retardation film. The retardation film is disposed on a side facing the transparent electrically conductive layer of the transparent electrically conductive film.

The slow axis of the polycycloolefin film used to form the optical unit according to the present invention has an angular variation that falls within a range of 4°. The in-plane retardation of a polycycloolefin film measured by using light having a wavelength of 550 nm at 23° C. ranges from 3 to 8 nm, and variation in the in-plane retardation falls within a range of 1.5 nm.

In the present specification, Re[550] represents an in-plane retardation value measured by using light having the wavelength of 550 nm at 23° C. Re[550] can be determined by an expression: Re[550]=(nx-ny)×d, where nx and ny represent the refractive indices of a film in the slow-axis direction and the fast-axis direction at the wavelength of 550 nm, respectively, and d (nm) represents the thickness of the film. The slow axis is the direction in which the in-plane refractive index is maximized.

The in-plane retardation of the retardation film used to form the optical unit according to the present invention is so set as to cancel little-varying, approximately constant in-plane retardation of the polycycloolefin film so that the retardation film and the transparent electrically conductive film as a whole have a desired in-plane retardation value.

The retardation film used to form the optical unit according to the present invention includes a quarter-wave retardation membrane, and the desired value described above can be set at about a quarter of the wavelength to be used. The retardation film used to form the optical unit according to the present invention can instead include a retardation membrane for angular viewing field compensation and a quarter-wave retardation membrane sequentially arranged from the side facing the transparent electrically conductive film, and the desired value described above can be set at about a quarter of the wavelength to be used. A situation in which the desired value described above is set at about a quarter of the wavelength to be used means a situation in which the desired value described above is set at about a quarter of each wavelength ideally across the visible light region. The in-plane retardation at the wavelength of 550 nm preferably ranges from 130 to 150 nm, more preferably from 140 to 146 nm.

The direction of the slow axis of the quarter-wave retardation membrane may be approximately parallel to the direction of the slow axis of the polycycloolefin film, that is, inclination of the direction of the slow axis of the quarter-wave retardation membrane with respect to the direction of the slow axis of the polycycloolefin film falls within a range of±2°. The configuration described above readily allows the retardation film to cancel the in-plane retardation of the polycycloolefin film.

The optical unit may further include a polarizing function laminate, and the polarizing function laminate may include a polarizing film and the retardation film described above. The retardation film may be disposed on a side facing the transparent electrically conductive layer of the transparent electrically conductive film, and the polarizing film may be disposed on the side opposite to the transparent electrically conductive film with respect to the retardation film.

The polarizing function laminate may have the function of producing circularly polarized light.

### Method for Manufacturing Transparent Electrically Conductive Film

A method for manufacturing the transparent electrically conductive film according to the present invention includes the steps of feeding a polycycloolefin film from a polycycloolefin film roll that is an elongated laminate including a polycycloolefin film wound in the form of a roll; carrying out a heating/winding process at a heating temperature ranging from 140 to 160° C. while winding the fed polycycloolefin film around a wind-up roll; and depositing a transparent electrically conductive layer on the polycycloolefin film having undergone the heating/winding process to produce a transparent electrically conductive film.

Thus, the direction of the slow axis of the polycycloolefin film can be aligned with the MD direction by winding the elongated laminate including the polycycloolefin film around the wind-up roll, that is, exerting constant tensile force on the polycycloolefin film and carrying out the heating/winding process at a temperature close to 165° C., which is the glass transition temperature (Tg) of the polycycloolefin film.

The heating temperature described above preferably ranges from 145 to 155° C., more preferably from 148 to 153° C.

### Method for Manufacturing Optical Unit

In a method for manufacturing the optical unit according to the present invention, the polarizing function laminate including the retardation film and the polarizing film is bonded to the transparent electrically conductive film manufactured by using the manufacturing method described above to produce the optical unit.

### <Polarizing Film>

A polyvinyl-alcohol-based resin containing oriented iodine and stretched in an in-air stretching (dry stretching) step, an in-boric-acid-solution stretching step, or any other stretching step may be used as the polarizing film used to form the optical unit according to the present invention.

An example of a representative method for manufacturing the polarizing film includes a manufacturing method including the step of dyeing a single layer made of a PVA-based resin and the step of stretching the dyed single layer, as described in Japanese Patent Laid-Open No. 2004-341515. Another example of the method for manufacturing the polarizing film includes a manufacturing method including the step of stretching a laminate of a PVA-based resin layer and a resin base material for stretching and the step of dyeing the stretched laminate, as described in Japanese Patent Laid-Open Nos. 51-069644, 2000-338329, and 2001-343521, International Publication No. WO 2010/100917, Japanese Patent Laid-Open Nos. 2012-073563 and 2011-2816. The latter example of the manufacturing method allows even a thin PVA-based resin layer to be stretched with no trouble, such as breakage resulting from the stretching, because the PVA-based resin layer is supported by the resin base material for stretching.

An example of the manufacturing method including the step of stretching a laminate and the step of dyeing the stretched laminate includes an in-air stretching (dry stretching) method, as described in above-mentioned Japanese Patent Laid-Open Nos. 51-069644, 2000-338329, and 2001-343521. From a viewpoint of ability to perform stretching at a high magnification factor and improvement in polarizing performance, the manufacturing method including the step of performing stretching in a boric acid aqueous solution, as described in International Publication No. WO 2010/100917 and Japanese Patent Laid-Open No. 2012-073563, is preferable, and the manufacturing method including the step of performing in-air auxiliary stretching before stretching in a boric acid aqueous solution (two-stage stretching method), as described in Japanese Patent Laid-Open No. 2012-073563, is particularly preferable. Further, a manufacturing method including the step of stretching a laminate of a PVA-based resin layer and a resin base material for stretching, then dyeing excessively the PVA-based resin layer, and then decolorizing partly the excessively-dyed PVA-based resin layer (excessive dyeing and partial decolorizing method) is also preferable, as described in above-mentioned Japanese Patent Laid-Open No. 2011-2816. The polarizing film used to form the optical laminate according to the present invention may be a polarizing film made of a polyvinyl-alcohol-based resin containing oriented iodine described above and stretched in the two-stage stretching step formed of the in-air auxiliary stretching and the in-boric-acid-solution stretching. The polarizing film used to form the optical laminate according to the present invention may instead be a polarizing film made of a polyvinyl-alcohol-based resin containing oriented iodine described above and produced by dyeing excessively a stretched laminate of the PVA-based resin layer and a resin base material for stretching, and then decolorizing partly the dyed laminate.

### <Retardation Film>

The retardation film used to form the optical unit according to the present invention includes a single-layer or multilayer retardation membrane.

### <Retardation Membrane>

The retardation membrane used to form the optical unit according to the present invention may be a retardation membrane produced by stretching a polymer film or a retardation membrane in which a liquid crystal material is oriented and fixed. In the present specification, the retardation membrane refers to a retardation membrane having birefringence in the in-plane direction and/or the thickness direction and achieving a predetermined function on the basis of the birefringence.

Examples of the retardation membrane may include a retardation membrane for antireflection (see paragraphs [0221], [0222], and [0228] in Japanese Patent Laid-Open No. 2012-133303), a retardation membrane for angular viewing field compensation (see paragraphs [0225] and [0226] in Japanese Patent Laid-Open No. 2012-133303), and an inclined-orientation retardation membrane for angular viewing field compensation (see paragraph [0227] in Japanese Patent Laid-Open No. 2012-133303).

Any known retardation membrane substantially having any of the functions described above can be used irrespective of, for example, the retardation value, the arrangement angle, the three-dimensional birefringence index, whether or not a single layer or a multilayer, and other factors.

In-plane birefringence Δn, which is nx-ny of the retardation membrane according to the present invention ranges from 0.001 to 0.2, preferably from 0.002 to 0.15.

The in-plane retardation value of the above-mentioned retardation membrane measured by using light having the wavelength of 550 nm at 23° C. (Re[550]) is preferably greater than the in-plane retardation value measured by using light having a wavelength of 450 nm (Re[450]). Any retardation membrane having the wavelength dispersion characteristic described above and having the ratio described above that falls within the range described above can manifest a greater amount of retardation at a longer wavelength and can provide an ideal retardation characteristic at each wavelength in the visible region. For example, in a case the retardation membrane is used in an organic EL display, a circularly polarizing plate or the like can be produced by producing a retardation membrane having the wavelength dependency described above as a quarter-wave plate and bonding the retardation membrane to a polarizer, whereby a neutral polarizer and display device having a small degree of dependence of hue on a wavelength can be achieved. On the other hand, when the ratio described above does not fall within the range describe above, the dependence of hue of reflected light on a wavelength increases, undesirably resulting in coloration of the polarizer and the display device.

The ratio between Re[550] and Re[450] (Re[450]/Re[550]) of the retardation membrane described above is greater than or equal to 0.8 but smaller than 1.0, more preferably ranges from 0.8 to 0.98.

The in-plane retardation value of the retardation membrane described above measured by using light having the wavelength of 550 nm at 23° C. (Re[550]) is preferably smaller than the in-plane retardation value measured by using light having a wavelength of 650 nm (Re[650]). Any retardation membrane having the wavelength dispersion characteristic described above provides a constant retardation value in the red region. For example, in a case where the retardation membrane is used in a liquid crystal display device, a phenomenon in which light leakage occurs depending on the viewing angle and a phenomenon in which a displayed image becomes reddish (also called reddish phenomenon) can be remedied.

The ratio between Re[650] and Re[550] (Re[550]/Re[650]) of the retardation membrane described above is greater than or equal to 0.8 but smaller than 1.0, preferably ranges from 0.8 to 0.97. When Re[550]/Re[650] falls within any of the ranges described above, in a case where the retardation membrane described above is used, for example, in an organic EL display, more excellent display characteristics can be obtained.

Re[450], Re[550], and Re[650] can be measured by using “AxoScan” (product name) manufactured by Axometrics, Inc.

In the present specification, NZ (also called Nz coefficient) refers to the ratio between nx-nz, which is the birefringence in the thickness direction, and nx-ny, which is the in-plane birefringence.

NZ of the retardation membrane according to the present invention ranges from −10 to 1.5, preferably from −8 to 1.4, more preferably from −6 to 1.3.

For example, in normal longitudinal stretching, in which a film is stretched in the longitudinal direction but is not fixed in the width direction, widthwise contraction occurs. The molecules in the film are more uniaxially oriented, and the refractive indices satisfy, for example, nx>ny=nz. In this case, the folding endurance of the film in the longitudinal direction thereof, which is the stretching direction, increases, whereas the folding endurance in the width direction greatly decreases. To solve the problem, the film is stretched in a state in which force for restricting the width is exerted on the film in an angular direction that intersects the stretching direction (for example, in lateral uniaxial stretching, force is so exerted on the film as to achieve a constant length in the longitudinal direction of the film, which is perpendicular to the width direction of the film, which is the stretching direction), whereby the molecules in the film can be oriented not only in the stretching direction but also in the angular direction that intersects the stretching direction, and the refractive indices can satisfy nx>ny>nz. High-level folding endurance in both the stretching direction and the width direction can therefore be achieved.

The absolute value of the photoelastic coefficient C (m²/N) of the retardation membrane described above at 23° C. ranges from 0.5×10⁻¹² to 100×10⁻¹² (m²/N), preferably from 1×10⁻¹² to 80×10⁻¹² (m²/N). It prevents a change in the retardation value caused by force acting on the retardation membrane due to contraction stress in the polarizing film, heat generated by a display panel, and a surrounding environment (humidity resistance, heat resistance). As a result, a display panel device having satisfactory display uniformity can be provided. The absolute value of the photoelastic coefficient C of the retardation membrane described above preferably ranges from 3×10⁻¹² to 45×10⁻¹², particularly preferably from 5×10⁻¹² to 40×10⁻¹². Setting C to fall within any of the ranges described above allows reduction in the change and unevenness in the retardation value resulting from force acting on the retardation membrane described above. Further, a tradeoff relationship between the photoelastic coefficient and An tends to occur, and the photoelastic coefficient that falls within any of the ranges described above allows display quality to be maintained with no decrease in degree of retardation manifestation.

A retardation membrane formed of a single film and showing inverse wavelength dispersion dependency (inverse wavelength dispersion characteristic) may preferably be used as the retardation membrane according to the present invention. “PURE-ACE WR” (product name) manufactured by TEIJIN Limited, a polycarbonate resin described in Japanese Patent No. 4938151, and a resin containing oligofluorene described in Japanese Patent Application No. 2013-214986 may be used as a retardation membrane showing the inverse dispersion.

In one embodiment, the retardation membrane according to the present invention is produced by stretching a polymer film to orient molecules therein.

As a method for stretching the polymer film described above, an any appropriate stretching method may be employed in accordance with the purpose. Examples of the stretching method described above appropriate for the present invention may include a lateral uniaxial stretching method, a longitudinal/lateral simultaneous biaxial stretching method, and a longitudinal/lateral successive biaxial stretching method. Examples of stretching means may include a tenter stretcher, a biaxial stretcher, or any other appropriate stretcher. The stretcher described above preferably includes temperature control means. When a film is stretched while heated, the internal temperature in the stretcher may be continuously changed or intermittently changed. The stretching step may be carried out once or may be divided into two or more steps. The stretching direction is preferably the film width direction (TD direction) or an oblique direction.

In oblique stretching, an oblique stretching process is continuously carried out as follows: An unstretched resin film is stretched in a direction inclining with respect to the width direction of the film by an angle that falls within the specific range described above with the film fed in the longitudinal direction. An elongated retardation membrane can thus be so produced that the angle between the width direction and the slow axis direction of the film (orientation angle θ) falls within the specific range described above.

The method for performing oblique stretching is not limited to a specific method and may be any method that allows an unstretched resin film to be continuously stretched in a direction inclining with respect to the width direction of the film by an angle that falls within the specific range described above to form a slow axis in the direction inclining with respect to the width direction of the film by the angle that falls within the specific range described above. An appropriate stretching method may be selected from conventionally known stretching methods described above, for example, in Japanese Patent Laid-Open Nos. 2005-319660, 2007-30466, 2014-194482, 2014-199483, and 2014-199483.

An appropriate temperature (stretching temperature) at which an unstretched resin film is stretched may be selected as appropriate in accordance with the purpose. The stretching is preferably performed on a polymer film, with respect to the glass transition temperature (Tg) of the polymer film, at a temperature in a range from Tg−20° C. to Tg+30° C. When the condition described above is employed, a uniform retardation value is likely to be achieved, and the film is unlikely to be crystallized (clouded). Specifically, the stretching temperature described above preferably ranges from 90 to 210° C., more preferably from 100 to 200° C., particularly preferably from 100 to 180° C. The glass transition temperature can be determined by using a DSC method compliant with JIS K7121 (1987).

As means for controlling the stretching temperature described above, any appropriate means may be employed. Examples of the temperature control means described above may include an air circulating, constant-temperature oven in which hot or cold air circulates, a heater using microwaves or far infrared radiation, and a roll, a heat pipe roll, and a metal belt that are heated for temperature control.

The magnification at which the unstretched resin film described above is stretched (stretching magnification) may be selected as appropriate in accordance with the purpose. The stretching magnification described above is preferably greater than 1 but smaller than or equal to 6, more preferably greater than 1.5 but smaller than or equal to 4.

Further, the film feed speed at the time of stretching is not limited to a specific value and preferably ranges from 0.5 to 30 m/min, more preferably from 1 to 20 m/min from viewpoints of mechanical precision, stability, and other factors. Under the stretching conditions described above, not only can target optical characteristics be obtained, but also a retardation membrane that excels in optical uniformity can be produced.

Further, as another embodiment, a retardation membrane formed as follows may be used: Polycycloolefin films, polycarbonate films, or any other films are bonded in sheet form to each other with an acrylic adhesive in such a way that the angle between the absorption axis of a polarizer and the slow axis of a half-wave plate is 15° and the angle between the absorption axis of the polarizer and the slow axis of a quarter-wave plate is 75°.

In another embodiment, the retardation membrane according to the present invention may be a laminate of retardation layers produced by orienting and fixing a liquid crystal material. Each of the retardation layers may be an oriented and solidified layer of liquid crystal compound. Since use of a liquid crystal compound allows the difference between nx and ny of the resultant retardation layer to significantly increase as compared with the difference in a non-liquid-crystal material, the thickness of a retardation layer for providing desired in-plane retardation can be significantly reduced. As a result, the thickness of the circularly polarizing plate (eventually, thickness of an organic EL display device) can be further reduced. In the present specification, the “oriented and solidified layer” refers to a layer in which liquid crystal compound molecules are oriented in a predetermined direction and the orientation state is fixed. In the present embodiment, representative examples of the oriented and solidified state include a state in which rod-shaped liquid crystal compound molecules are so oriented as to be aligned with the slow axis direction of the retardation layer (homogeneous orientation) and a state in which the slow axis is so oriented as to be aligned with direction of a normal to the in-plane direction (homeotropic orientation). An example of the liquid crystal compound may include a liquid crystal compound having a nematic liquid crystal phase (nematic liquid crystal material). As the liquid crystal compound described above, for example, a liquid crystal polymer or a liquid crystal monomer can be used. The mechanism in accordance with which the liquid crystal property of the liquid crystal compound manifests may be the lyotropic or thermotropic mechanism. A liquid crystal polymer and a liquid crystal monomer may be used alone or in combination.

In the case where the liquid crystal compound is a liquid crystal monomer, the liquid crystal monomer is preferably a polymerizable, cross-linkable monomer. The reason for this is that polymerizing or cross-linking liquid crystal monomer molecules allows fixation of the state in which the liquid crystal monomer molecules are oriented. After the liquid crystal monomer molecules are oriented, the liquid crystal monomer molecules are, for example, polymerized or cross-linked, whereby the orientation state described above can be fixed. At this point, the liquid crystal monomer molecules are polymerized to form a polymer, and the liquid crystal monomer molecules are cross-linked to form a three-dimensional mesh structure, but the thus formed polymer and structure both have no liquid crystal properties. The formed retardation layer therefore does not experience temperature-change-induced transition, for example, to a liquid crystal phase, a glass phase, or a crystal phase, which is specific to a liquid crystal compound. As a result, the retardation layer is changed to an extremely stable retardation layer that is not affected by a change in temperature.

The temperature range over which a liquid crystal monomer shows liquid crystal properties varies in accordance with the type of the liquid crystal monomer. Specifically, the temperature range preferably ranges from 40 to 120° C., more preferably from 50 to 100° C., most preferably from 60 to 90° C.

As the liquid crystal monomers described above, any appropriate liquid crystal monomer may be employed. For example, polymerizable mesogenic compounds described, for example, in National Publication of International Patent Application No. 2002-533742 (WO 00/37585), EP 358208 (U.S. Pat. No. 5,211,877), EP 66137 (U.S. Pat. No. 4,388,453), WO 93/22397, EP 0261712, DE 19504224, DE 4408171, and GB 2280445. Specific examples of the polymerizable mesogenic compound may include LC242 (product name) manufactured by BASF SE, E7 (product name) manufactured by Merck KGaA, and LC-Sillicon-CC3767 (product name) manufactured by Wacker-Chem AG. The liquid crystal monomer is preferably, for example, a nematic liquid crystal monomer.

The oriented and solidified layer of the liquid crystal compound may be formed by performing an orientation treatment on a surface of a predetermined base material, coating a coating liquid containing a liquid crystal compound on the surface to orient the liquid crystal compound molecules in the direction corresponding to the orientation treatment, and fixing the orientation state. In one embodiment, the base material may be any appropriate resin film, and the oriented and solidified layer formed on the base material may be transferred onto a surface of the polarizing film. At this point, the oriented and solidified layer is so disposed that the angle between the absorption axis of the polarizing film and the slow axis of the liquid crystal oriented and solidified layer is 15°. The retardation of the liquid crystal oriented and solidified layer is λ/2 of the wavelength of 550 nm (about 270 nm). Further, a liquid crystal oriented and solidified layer having a retardation of λ/4 of the wavelength of 550 nm (about 140 nm) is formed on the transferable base material in the same manner described above and so layered on the side of the half-wave plate of the laminate of the polarizing film and the half-wave plate that the angle between the absorption axis of the polarizing film and the slow axis of the quarter-wave plate is 75°.

As the orientation treatment described above, any appropriate orientation treatment may be employed. Specifically, a mechanical orientation treatment, a physical orientation treatment, and a chemical orientation treatment may be listed as candidates of the orientation treatment. Specific examples of the mechanical orientation treatment may include a rubbing treatment and a stretching treatment. Specific examples of the physical orientation treatment may include a magnetic field orientation treatment and an electric field orientation treatment. Specific examples of the chemical orientation treatment may include an oblique evaporation method and an optical orientation treatment. Treatment conditions under which each of the orientation treatments is performed may be any appropriate conditions in accordance with the purpose.

The orientation of the liquid crystal compound is performed by treating the liquid crystal compound at a temperature at which the liquid crystal compound shows a liquid phase in accordance with the type of the liquid crystal compound. Such thermal treatment allows the liquid crystal compound to act in the liquid crystal state and the liquid crystal compound to be oriented in accordance with the direction in which the orientation treatment has been performed on the surface of the base material.

The orientation state is fixed in one embodiment by cooling the liquid crystal compound oriented as described above. In the case where the liquid crystal compound is a polymerizable monomer or a cross-linkable monomer, the orientation state is fixed by performing polymerization or cross-linkage on the liquid crystal compound oriented as described above.

A specific example of the liquid crystal compound and the method for forming the oriented and solidified layer are described in detail in Japanese Patent Laid-Open No. 2006-163343. The description in Patent Laid-Open No. 2006-163343 is incorporated by reference in the present specification.

### Protective Membrane

The protective membrane that protects a transparent resin material used to form the optical unit according to the present invention may be made, for example, of a cycloolefin-based resin, such as a norbornene-based resin, an olefin-based resin, such as polyethylene and polypropylene, a polyester-based resin, a (meta)acrylic resin.

The thickness of the protective membrane used with the optical laminate according to the present invention ranges from 10 to 50 μm, preferably from 15 to 45 μm, and a surface treatment layer, such as an anti-glare layer or an antireflection layer, may be provided as appropriate.

The amount of humidity that passes through the protective membrane used with the optical laminate according to the present invention is smaller than or equal to 200 g/m², preferably smaller than or equal to 170 g/m², more preferably smaller than or equal to 130 g/m², particularly preferably smaller than or equal to 90 g/m².

### Transparent Electrically Conductive Film

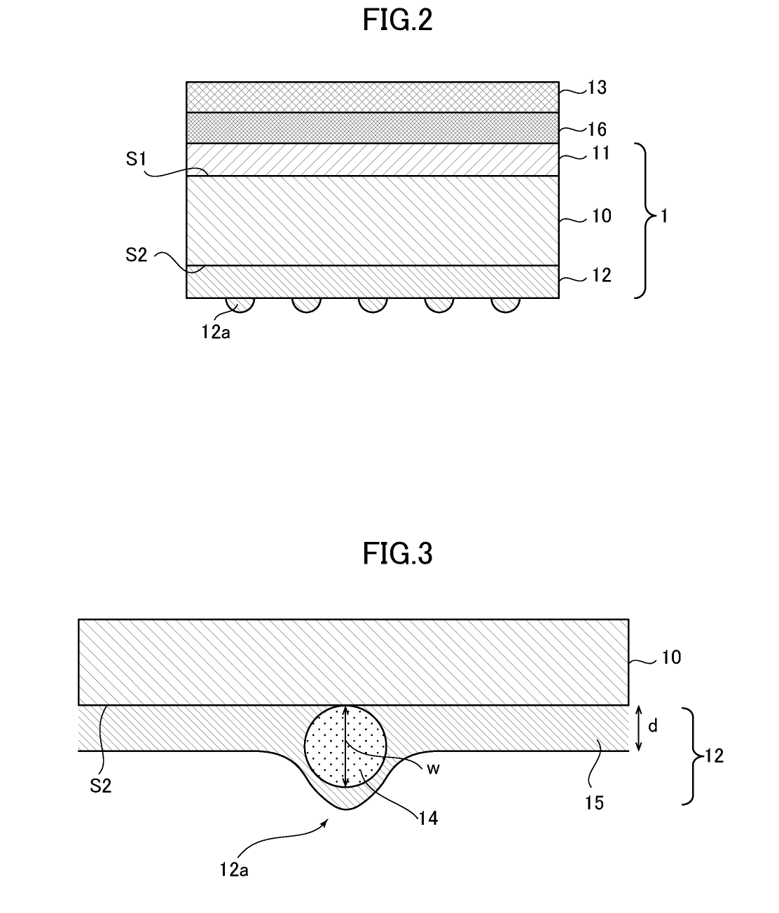

FIG. 2 is a diagrammatic cross-sectional view of a transparent electrically conductive film according to an embodiment of the present invention. The transparent electrically conductive film in FIG. 2 includes a base material laminate 1 and a transparent electrically conductive layer 13.

The base material laminate 1 described above includes a polycycloolefin film 10, a first curable resin layer 11, which is formed on a first principal surface S1 of the polycycloolefin film 10, and a second curable resin layer 12, which is formed on a second principal surface S2, which is another principal surface of the polycycloolefin film 10 and located on the side opposite to the first principal surface S1. Further, an optical adjustment layer 16 is provided between the first curable resin layer 11 and the transparent electrically conductive layer 13. The second curable resin layer 12 has a plurality of spherical particles 14 and a binder resin layer 15, which fixes the spherical particles to the surface of the polycycloolefin film 10, as shown in FIG. 3. Since the second curable resin layer 12 has protrusions 12a present on the surface thereof, when the transparent electrically conductive film is wound in a roll-to-roll manufacturing method, blocking between one turn of the transparent electrically conductive film and another turn thereof can be avoided. The base material laminate 1 may be formed of only the polycycloolefin film 10 or the polycycloolefin film 10 and the first curable resin layer or the second curable resin layer, but the first curable resin layer 11 on the side where the transparent electrically conductive layer 13 is formed, the polycycloolefin film 10, and the second curable resin layer 12 are preferably provided in this order.

### Transparent Electrically Conductive Layer

The transparent electrically conductive layer is preferably a layer made of a metal oxide. The metal oxide is preferably a metal oxide of at least one metal selected from a group comprised of indium, tin, zinc, gallium, antimony, titanium, silicon, zirconium, magnesium, aluminum, gold, silver, copper, palladium, and tungsten. The metal oxide may further contain another metal atom contained in the group described above as required. An indium tin composite oxide (ITO) or an indium zinc composite oxide is particularly preferable among others. Still instead, an indium oxide into which a tetravalent metal ion or a divalent metal ion is doped (In₂O₃) is used. The thus formed indium-based composite oxide layer is characterized by high transmittance of at least 80% in the visible light region (380 to 780 nm) and low surface resistance per unit area (lower than or equal to 300 Ω/□: ohms per square).

The surface resistance of the indium-based composite oxide layer described above is preferably lower than or equal to 300 Ω/□, more preferably lower than or equal to 270 Ω/□. A transparent electrically conductive film having small surface resistance, such as the values described above, is produced, for example, by forming an amorphous layer made of an indium-based composite oxide on the curable resin layer in a sputtering or vacuum evaporation process and thermally treating the resultant structure at a temperature ranging from 120 to 200° C. for 30 to 90 minutes to change the amorphous layer to a crystalline layer. Means for transforming the amorphous layer into a crystalline layer is not limited to specific means and may, for example, be an air circulating oven or an IR heater.

### (Definition of Crystalline State)

After the transparent electrically conductive film having the transparent electrically conductive layer formed on the base material laminate is immersed in hydrochloric acid having a concentration of 5 wt % at 20° C. for 15 minutes and rinsed and dried, and 15-mm inter-terminal resistance is measured with a tester, the transformation of the amorphous ITO membrane into a crystalline ITO membrane is considered to be completed when the inter-terminal resistance is not greater than 10 kΩ.

The thickness of the transparent electrically conductive layer preferably ranges from 15 to 50 nm, more preferably from 20 to 40 nm, further preferably from 25 to 35 nm. When the thickness of the transparent electrically conductive layer is smaller than 15 nm, the electrical resistance of the membrane surface increases, and a continuous coating is unlikely to be produced. When the thickness of the transparent electrically conductive layer is greater than 50 nm, the transparency decreases or otherwise deteriorates in some cases. The transparent electrically conductive layer may instead have a structure in which a plurality of transparent electrically conductive layers having different compositions are laminated on each other.

Arithmetic average surface roughness Ra of the surface of the transparent electrically conductive layer described above in a field of view of 452×595 μm is preferably greater than 0 nm but smaller than or equal to 10 nm, more preferably greater than 0 nm but smaller than or equal to 9 nm, further preferably greater than 0 nm but smaller than or equal to 7 nm from a viewpoint of improvement in transparency. The difference between the arithmetic average surface roughness Ra of the surface of the second curable resin layer in the field of view of 452×595 μm and the arithmetic average surface roughness Ra of the surface of the transparent electrically conductive layer described above in the field of view of 452×595 μm is preferably greater than or equal to 5 nm, more preferably greater than or equal to 10 nm, further preferably greater than or equal to 15 nm.

The transparent electrically conductive layer described above may contain metal nanowires or metal meshes.

### (Metal Nanowires)

Each of the metal nanowires refers to an electrically conductive substance made of a metal, having a needle-like or thread-like shape, and having a nanometer-order diameter. The metal nanowires may have a linear or curved shape. When a transparent electrically conductive layer containing metal nanowires is used, a satisfactory electrical conduction path can be formed even when a small amount of metal nanowires is contained because the metal nanowires form a mesh pattern, and a transparent electrically conductive film having small electrical resistance can be produced. Further, since the metal nanowires form a mesh pattern, a transparent electrically conductive film having high optical transmittance can be produced by forming openings in the clearances formed by the meshes.

As a metal of which the metal nanowires described above are made, any appropriate metal having high electrical conductivity may be used.

Examples of the metal of which the metal nanowires described above are made may include, for example, silver, gold, copper, and nickel. Any of the metals described above having undergone a plating treatment (gold plating treatment, for example) may instead be used. Among the metals described above, silver, copper, or gold is preferable from a viewpoint of electrical conductivity, and silver is more preferable.

### (Metal Meshes)

A transparent electrically conductive layer including metal meshes is formed on the base material laminate described above in such a way that metal thin wires form a lattice pattern. The same metal as the metal of which the metal nanowires described above are made may be used. A transparent electrically conductive layer including metal meshes may be formed in any appropriate method. The transparent electrically conductive layer can be produced, for example, by applying a photosensitive composition containing a silver salt (composition for forming a transparent electrically conductive layer) onto the base material laminate and then performing light exposure and development to shape the metal thin wires in a predetermined pattern.

### Curable Resin Layers

A cycloolefin-based resin itself is very likely to be scratched. Since the polycycloolefin film 10 is likely to be scratched in each of the steps of forming the transparent electrically conductive layer, patterning the transparent electrically conductive layer, or incorporating the transparent electrically conductive layer in an electronic apparatus, the first curable resin layer and the second curable resin layer are preferably formed as curable resin layers on opposite surfaces of the polycycloolefin film 10.

Each of the curable resin layers is a layer produced by curing a curable resin. The curable resin may be a resin that cures on the basis of a thermal cure mechanism, an active energy ray cure mechanism, or both of them. A cross-linker, an initiator, a sensitizer, or any other agent may be used as required along with the curable resin. The thickness of each of the first curable resin layer and the second curable resin layer preferably independently ranges from 0.5 to 5 μm, more preferably from 0.7 to 3 μm, most preferably from 0.8 to 2 μm. The first curable resin layer and the second curable resin layer are each produced by applying a curable resin and a resin composition containing a cross-linker, an initiator, a sensitizer, or any other agent added as required onto a transparent resin film, and drying, in a case where the resin composition contains a solvent, the solvent, and applying heat, active energy rays, or both of them onto the resultant structure. The heat can be generated by using known means, such as an air circulating oven and an IR heater, but not limited to the methods described above. Examples of the active energy rays include ultraviolet rays, electron rays, and gamma rays, but not particularly limited thereto. The curable resin is preferably an acrylic resin or an epoxy-based resin, more preferably an acrylic resin.

The first curable resin layer 11 or the second curable resin layer 12 preferably includes the plurality of spherical particles 14 and the binder resin layer 15, which fixes the spherical particles described above to the surface of the polycycloolefin film 10. In particular, the second curable resin layer 12 more preferably includes the plurality of spherical particles 14 described above and the binder resin layer 15 described above. FIG. 3 is a partially enlarged view showing the configuration of the second curable resin layer 12 in FIG. 2. The second curable resin layer 12 includes the plurality of spherical particles 14 and the binder resin layer 15, which fixes the spherical particles 14 described above to the surface of the polycycloolefin film 10. Reference sign w denotes the most frequent particle diameter of the spherical particles 14, and reference sign d denotes the thickness of the binder resin layer 15. On the outer surface of the second curable resin layer 12, that is, on the surface that is not in contact with the polycycloolefin film 10, the portion where each of the spherical particles 14 is present has a convex shape that protrudes by about the difference w−d, and the portion where no spherical particle 14 is present has a approximately flat shape. Part of the binder resin layer 15 is thinly formed on the upper surface of each of the spherical particles 14. The term “most frequent particle diameter” refers to a particle diameter corresponding to a local maximum in the particle distribution. The term “thickness of binder resin layer” refers to the thickness of the flat portions where no spherical particle is present. In the second curable resin layer 12, the relationship between the most frequent particle diameter w of the spherical particles 14 and the thickness d of the binder resin layer 15 is as follows: w−d is preferably greater than 0 μm but smaller than or equal to 1.2 μm; more preferably ranges from 0.1 to 1.0 μm; further preferably ranges from 0.3 to 0.9 μm. The relationship described above can more reliably achieve blocking resistance that allows the transparent electrically conductive film to go through the roll-to-roll manufacturing method with influence of the particles on haze suppressed.

The arithmetic average surface roughness Ra of the surface of the first curable resin layer is preferably greater than 0 nm but smaller than or equal to 10 nm, more preferably greater than 0 nm but smaller than or equal to 9 nm, further preferably greater than 0 nm but smaller than or equal to 7 nm from the viewpoint of improvement in transparency.

The arithmetic average surface roughness Ra of the surface of the second curable resin layer is preferably greater than 5 nm but smaller than or equal to 100 nm, more preferably greater than 7 nm but smaller than or equal to 70 nm, further preferably greater than 10 nm but smaller than or equal to 60 nm. When the arithmetic average surface roughness Ra falls within any of the ranges described above, the blocking resistance that allows the transparent electrically conductive film to go through the roll-to-roll manufacturing method can be improved.

The arithmetic average surface roughness Ra of the second curable resin layer is preferably greater than the arithmetic average surface roughness Ra of the first curable resin layer. As a result, the blocking resistance that allows the transparent electrically conductive film to go through the roll-to-roll manufacturing method can be achieved, and the amount of white cloudiness (haze) on the side facing the transparent electrically conductive layer can be reduced. Further, the difference between the arithmetic average surface roughness Ra of the surface of the second curable resin layer in the field of view of 452×595 μm and the arithmetic average surface roughness Ra of the surface of the first curable resin layer in the field of view of 452×595 μm is preferably greater than or equal to 5 nm, more preferably greater than or equal to 10 nm, further preferably greater than or equal to 15 nm.

As the spherical particles described above, transparent spherical particles made, for example, of any of a variety of metal oxides, glass materials, and plastic materials can be used with no limitation. Examples of the spherical particles may include inorganic particles made, for example, of silica, alumina, titania, zirconia, or a calcium oxide, crosslinked or non-crosslinked organic particles made of polymethyl methacrylate, polystyrene, polyurethane, an acrylic resin, an acryl-styrene copolymer, benzoguanamine, melamine, polycarbonate, or any of a variety of other polymers, and silicone particles. One or at least two of the particles described above can be selected and used as appropriate, but the organic particles are preferable. As the organic particles, an acrylic resin is preferable from viewpoints of sphericity and heat resistance.

The content of the spherical particles in the first curable resin layer described above preferably ranges from 0.0000 to 0.0020 weight parts with respect to 100 weight parts of the solid content of the resin composition, more preferably from 0.0000 to 0.0015 weight parts, further preferably from 0.0000 to 0.0010 weight parts. The content of the spherical particles in the second curable resin layer described above preferably ranges from 0.0010 to 0.0300 weight parts with respect to 100 weight parts of the solid content of the resin composition, more preferably from 0.0015 to 0.0200 weight parts, further preferably from 0.0020 to 0.0150 weight parts. When the content of the spherical particles in the first curable resin layer described above or the second curable resin layer described above falls within any of the ranges described above, the arithmetic average surface roughness Ra on both surfaces can be separately adjusted, whereby base raised portions sufficient for imparting the blocking resistance and satisfactory slippage are readily formed, and haze of the transparent electrically conductive film resulting from light scattered by the spherical particles is reduced, so that the viewability tends to increase.

As the binder resin material used to form the binder resin layer described above, any material that allows fixation of the spherical particles can be employed. The binder resin is, for example, a curable resin composition cured with ultraviolet rays or electron rays. The curable resin composition preferably contains a polyfunctional acrylate polymer, such as pentaerythritol and dipentaerythritol, a polymer produced by adding an acrylic acid to a glycidyl-acrylate-based polymer to cause them to react with each other, and a polymerization initiator.

### Optical Adjustment Layer

The transparent electrically conductive film may further include at least one optical adjustment layer 16 between the first curable resin layer 11 and the transparent electrically conductive layer 13, as shown in FIG. 2. To increase the transmittance of the transparent electrically conductive film, or in a case where the transparent electrically conductive layer 13 is patterned, the optical adjustment layer 16 is used to reduce the difference in transmittance or reflectance between the patterned portion where the pattern is left and the opening where no pattern is left so as to provide a transparent electrically conductive film that excels in viewability.

The optical adjustment layer is made of an inorganic substance, an organic substance, or a mixture of an inorganic substance and an organic substance. Examples of the material of which the optical adjustment layer is made may include an inorganic substance, such as NaF, Na₃AlF₆, LiF, MgF₂, CaF₂, MgF₂, SiO₂, LaF₃, CeF₃, Al₂O₃, TiO₂, Ta₂O₅, ZrO₂, ZnO, ZnS, SiOx (x is greater than or equal to 1.5 but smaller than 2), and an organic substance, such as an acrylic resin, a urethane resin, a melamine resin, an alkyd resin, and a siloxane-based polymer. In particular, as the organic substance, a thermosetting resin made of a mixture of a melamine resin, an alkyd resin, and an organic silane condensate is preferably used. The optical adjustment layer can be formed by using any of the materials described above in a coating method, such as a gravure coating method and a bar coating method, a vacuum evaporation method, a sputtering method, and an ion plating method.

The thickness of the optical adjustment layer preferably ranges from 10 to 200 nm, more preferably from 20 to 150 nm, further preferably from 20 to 130 nm. When the thickness of the optical adjustment layer is excessively small, a continuous coating is unlikely to be achieved. On the other hand, when the thickness of the optical adjustment layer is excessively large, the transparency of the transparent electrically conductive film tends to decrease, and cracking tends to occur in the optical adjustment layer.

The optical adjustment layer may contain nanoparticles having an average particle diameter ranging from 1 to 500 nm. The content of the nanoparticles in the optical adjustment layer preferably ranges from 0.1 to 90 wt %. The average particle diameter of the nanoparticles contained in the optical adjustment layer preferably ranges from 1 to 500 nm, as described above, more preferably from 5 to 300 nm. The content of the nanoparticles in the optical adjustment layer more preferably ranges from 10 to 80 wt %, further preferably from 20 to 70 wt %. The nanoparticles contained in the optical adjustment layer readily allow adjustment of the refractive index of the optical adjustment layer itself.

Examples of an inorganic oxide of which the nanoparticles are made may include a silicon oxide (silica), hollow nano-silica, a titanium oxide, an aluminum oxide, a zinc oxide, a tin oxide, a zirconium oxide, and a niobium oxide. Among them, particles made of a silicon oxide (silica), a titanium oxide, an aluminum oxide, a zinc oxide, a tin oxide, a zirconium oxide, and a niobium oxide are preferable. One of the materials described above may be used alone, or two or more of them may be used in combination.

### Polycycloolefin Film

The polycycloolefin film, which is a film base material that supports a metal wiring layer, may be formed of a single layer or multiple layers. The thickness of the polycycloolefin film preferably ranges from 20 to 200 μm from viewpoints of transparency and ease of handling.

The polycycloolefin film has a plurality of protrusions on opposite surfaces on each of which a metal wiring layer is formed. Providing the plurality of protrusions on the surfaces of the polycycloolefin film allows slippage and wear resistance to be imparted to the polycycloolefin film. Further, when continuous deposition of the metal wiring layers is performed, the deposition speed can be increased to improve productivity with high quality of the metal wiring layers maintained.

The protrusions each has an outer diameter D greater than 0 μm but smaller than or equal to 3 μm, preferably ranging from 0.1 to 2 μm in a plan view of the surfaces of the polycycloolefin film on the sides where the metal wiring layers are formed. The outer diameter of the protrusions can be measured, for example, by observing images magnified at a predetermined factor and showing the surfaces of the polycycloolefin film on the sides where the metal wiring layers are formed. When the outer diameter D is smaller than or equal to 3 μm, a situation in which the metal wiring is broken in the vicinity of the boundary between each of the surfaces of the polycycloolefin film and the surface of each of the protrusions can be reliably avoided.

The height of the protrusions is preferably greater than 0 μm but smaller than or equal to 3 μm, more preferably ranges from 0.1 to 2 μm with respect to the flat surface of the polycycloolefin film.

The protrusions have a approximately dome-like shape in the present embodiment, and the polycycloolefin film has a approximately circular in-plane cross-sectional shape and a approximately semicircular cross-sectional shape in the thickness direction. It is, however, noted that the protrusion in the present invention may have any non-dome-like shape that allows slippage and wear resistance to be imparted to the polycycloolefin film and high-quality metal wiring layers to be deposited continuously at high speed.

Examples of means for providing the protrusions on the polycycloolefin film may include a method for dispersing a lubricant in the polycycloolefin film and a method for applying a binder in which a plurality of particles are dispersed onto the surface of the film.

The polycycloolefin film is available, for example, from Zeon Corporation.

### (Metal Wiring Layers)

The metal wiring layers are formed, for example, in a mesh pattern that imparts light transparency thereto. The mesh pattern of the metal wiring layers described above is not limited to a specific pattern and is, for example, a square lattice pattern, a rhombus lattice pattern, or a polygonal lattice pattern.

The metal wiring layers described above are not necessarily made of a specific material and may be made of any material having electrical conductivity, preferably silver or copper or an alloy thereof, more preferably copper.

The linewidth of the metal wiring layers described above is greater than 5 μm but smaller than 8 μm, preferably greater than 5.5 μm but smaller than or equal to 7 μm. The linewidth range described above can prevent wiring breakage of the wiring due to the protrusions on the film base material. When the linewidth is smaller than or equal to 5 μm, the mesh pattern of the metal wiring layers is unlikely to be visually recognized, but the frequency of breakage of the metal wiring increases due to the protrusions on the film base material, resulting in decrease in quality and reliability of the metal wiring in volume production. On the other hand, when the linewidth is greater than or equal to 8 μm, the mesh pattern of the metal wiring layers is clearly visually recognized.

The thickness of the metal wiring layers is greater than or equal to 0.1 μm but smaller than 0.5 μm, preferably greater than 0.1 μm but smaller than or equal to 0.4 μm, further preferably ranges from 0.15 to 0.35 μm. The mesh pattern of the metal wiring layers is more unlikely to be visually recognized when the thickness of the metal wiring layers is smaller than, for example, 2 μm. The configuration described above prevents the side surfaces of the metal wiring layers from shining when external light is incident on the touch sensor in an oblique direction, whereby the mesh pattern is unlikely to be visually recognized.

The metal wiring layers are characterized by a flat shape thereof, and the ratio of the linewidth to the thickness (linewidth/thickness) is preferably greater than or equal to 10 but smaller than 80, more preferably rages from 15 to 50. A touch sensor that satisfies the ratio described above excels in productivity, is unlikely to experience breakage of the metal wiring, and is likely to prevent the mesh pattern of the metal wiring layers from being visually recognized.

The cross-sectional area of each of the metal wiring layers preferably ranges from 0.5 to 4 μm², more preferably from 0.5 to 3.2 μm², particularly preferably from 0.5 to 2.5 μm² to achieve electrical conductivity necessary for the touch panel sensor.

The pitch distance between the metal wiring layers preferably ranges from 200 to 800 μm, more preferably from 350 to 650 μm to achieve sufficient light transparency. The aperture ratio of the metal wiring layers preferably ranges from 95 to 99%, more preferably from 96 to 99%.

A method for forming the metal wiring layers described above, for example, includes depositing a metal layer on the entire surface of a film base material, then layering a predetermined resist pattern on the metal layer, removing the metal layer in an unnecessary region so that mesh-shaped metal wiring layers are formed by etching, and then stripping the resist. The metal layer described above can be deposited, for example, by using a sputtering method, a plating method, or the combination thereof.

### Organic EL Display Device

The organic EL display device according to the present invention includes the optical unit described above and an organic EL display panel, and the optical unit is disposed on the visually recognized side of the organic EL display panel and further so disposed that the transparent electrically conductive film is located between the polarizing film and the organic EL display panel.

A window can be disposed, although optionally, on the visually recognized side of the laminate for the organic EL display device.

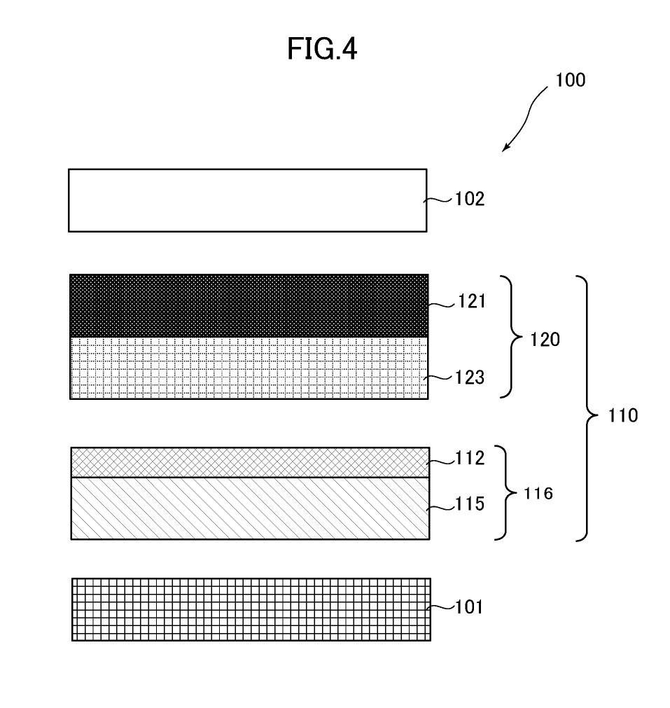

FIG. 4 is a cross-sectional view showing an embodiment of the organic EL display device according to the present invention. An organic EL display device 100 includes an optical unit 110 and an organic EL display panel 101. The optical unit 110 is disposed on the visually recognized side of the organic EL display panel 101.

A transparent window 102 can be disposed, although optionally, on the visually recognized side of the optical unit 110.

The optical unit 110 includes a transparent electrically conductive film 116, a polarizing film 121, and a retardation film 123.

The polarizing film 121 is disposed on the side opposite to the transparent electrically conductive film 116 with respect to the retardation film 123. In this case, the polarizing film 121 and the retardation film 123 form a polarizing function laminate 120. The polarizing function laminate 120 is intended, for example, to produce circularly polarized light so as to prevent light incident through the visually recognized side of the polarizing film 121 from being internally reflected and exiting through the visually recognized side, and to compensate the angular field of view.

A protective film may be glued, although optionally, onto one surface or both surfaces of the polarizing film 121.

The optical unit 110 is so disposed that the transparent electrically conductive film 116 is located between the polarizing film 121 and the organic EL display panel 101.

The transparent electrically conductive film 116 includes a polycycloolefin film 115 and a transparent electrically conductive layer 112.

Angular variation in the slow axis of the polycycloolefin film 115 falls within an angular range of 4°, and the in-plane retardation of the polycycloolefin film 115 described above measured by using light having the wavelength of 550 nm at 23° C. falls within a range from 3 to 8 nm, and variation in the in-plane retardation falls within a range of 1.5 nm. The in-plane retardation of the retardation film 123 is so set as to cancel the in-plane retardation of the polycycloolefin film 115 so that the retardation film 123 and the transparent electrically conductive film 116 as a whole have a desired in-plane retardation value.

In the present embodiment, since the in-plane retardation of the retardation film 123 cancels the little-varying, approximately constant in-plane retardation of the polycycloolefin film 115 that falls within the range from 3 to 8 nm so that the retardation film 123 and the transparent electrically conductive film 116 as a whole have in-plane retardation of about a quarter of the wavelength, the hue of reflected light has a satisfactory value.

The retardation film 123 includes, although optionally, a quarter-wave retardation membrane, and the desired value described above is about a quarter of the wavelength.

The retardation film 123 includes, although optionally, a retardation membrane for angular viewing field compensation and a quarter-wave retardation membrane arranged sequentially from the side facing the transparent electrically conductive film 116, and the desired value described above is about a quarter of the wavelength.

Inclination of the direction of the slow axis of the quarter-wave retardation membrane described above with respect to the direction of the slow axis of the polycycloolefin film 115 falls, although optionally, within a range of±3°. The configuration described above allows not only the retardation film 123 to readily cancel the in-plane retardation of the polycycloolefin film 115 but also reduction in the reflectance at which the light incident through the polarizing film-side surface of the optical unit is reflected.

Inclination of the direction of the slow axis of the quarter-wave retardation membrane described above with respect to the direction of the slow axis of the polycycloolefin film 115 falls, although optionally, within a range of 90°35 3°. The configuration described above allows not only the retardation film 123 to readily cancel the in-plane retardation of the polycycloolefin film 115 but also reduction in the reflectance at which the light incident through the polarizing film-side surface of the optical unit is reflected.

### EXAMPLES

The transparent electrically conductive film including the polycycloolefin film and the transparent electrically conductive layer according to the present invention and the method for manufacturing the transparent electrically conductive film, the roll of the laminate including the transparent electrically conductive film, the optical unit including the transparent electrically conductive film and the method for manufacturing the optical unit, and the organic EL display device including the optical unit will be further described with reference to the following Examples. It is noted that the transparent electrically conductive film including the polycycloolefin film and the transparent electrically conductive layer according to the present invention and the method for manufacturing the transparent electrically conductive film, the roll of the laminate including the transparent electrically conductive film, the optical unit including the transparent electrically conductive film and the method for manufacturing the optical unit, and the organic EL display device including the optical unit are not limited only to these Examples.

### Example A1

### Transparent Electrically Conductive Film

### (Formation of Curable Resin Layers)

A spherical-particles-containing curable resin composition containing 100 weight parts of an ultraviolet curable resin composition (product name “UNIDIC (registered trademark) RS29-120” manufactured by DIC Corporation) and 0.002 weight parts of acrylic spherical particles having a most frequent particle diameter of 1.9 μm (product name “MX-180TA” manufactured by Soken Chemical & Engineering Co., Ltd.) was prepared. The prepared spherical-particles-containing curable resin composition was applied onto one surface of an elongated polycycloolefin film having a thickness of 50 μm and a width of 1550 mm (product name “ZEONOR (registered trademark)” manufactured by Zeon Corporation) to form an applied layer.

The applied layer was then irradiated with ultraviolet rays radiated to the side where the applied layer was formed to form a second curable resin layer having a thickness of 1.0 μm. A first curable resin layer was formed to have a thickness of 1.0 μm on the other surface of the polycycloolefin film by using the same method described above except that no spherical particles were contained.

Further, an organic-inorganic-hybrid resin formed of zirconium oxide particles having an average particle diameter of 30 nm and a binder made of an acrylic resin (product name: OPSTAR Z7412 (registered trademark) manufactured by JSR Corporation, solid content: 20%, solvent: 80%) was formed as the optical adjustment layer on the first curable resin layer to form a base material laminate, and a roll of the base material laminate wound in the shape of a roll was produced.

### (Heating/Winding Process)

The base material laminate fed from the roll of the resultant base material laminate was then loaded into an air circulating oven, and a heating/winding process was carried out at 150° C. for 3 minutes while the base material laminate was wound around a wind-up roll in the roll-to-roll method. A roll of the base material laminate having undergone the heating/winding process and having been wound in the form of a roll was thus produced.

### (Formation of Transparent Electrically Conductive Layer)

The base material laminate fed from the resultant roll of the resultant base material laminate having undergone the heating/winding process was then loaded into a windup-type sputtering apparatus to form an amorphous indium tin oxide layer having a thickness of 27 nm on the surface of the first curable resin layer. The polycycloolefin film on which the amorphous indium tin oxide layer was formed was then loaded into the air circulating oven in the roll-to-roll method, and a heat treatment was performed at 130° C. for 90 minutes to transform the amorphous transparent electrically conductive layer into a crystalline transparent electrically conductive layer. A transparent electrically conductive film including the transparent electrically conductive layer having a surface resistance of 100 Ω/□ was thus formed, and a roll of the transparent electrically conductive film wound in the form of a roll was produced.

### Retardation Membrane

Polymerization was performed by using a batch polymerization apparatus formed of two vertical reactors each including a stirring blade and a reflux cooler controlled at 100° C. 9,9-[4-(2-hydroxyethoxy)phenyl]fluorene (BHEPF), isosorbide (ISB), diethylene glycol (DEG), diphenyl carbonate (DPC), and magnesium acetate tetrahydrate were prepared at a molar ratio BHEPF/ISB/DEG/DPC/magnesium acetate=0.438/0.537/0.025/1.005/1.00×10⁻⁵. After the interior of each of the reactors was sufficiently substituted for nitrogen (oxygen concentration ranging from 0.0005 to 0.001 vol %), the temperature was increased with a heating medium, and stirring was initiated when the internal temperature reached 100° C. After 40 minutes has elapsed since the temperature increase started, the internal temperature was so increased as to reach 220° C., and the temperature was controlled to be maintained and decrease in pressure was initiated at the same time. The pressure was so lowered as to reach 13.3 kPa in 90 minutes after the temperature reached 220° C. Phenol vapor produced as a by-product in the polymerization reaction was guided into the reflux cooler at 100° C., a monomer component slightly contained in the phenol vapor was returned into the reactor, and phenol vapor that has not condensed was guided into a condenser at 45° C. and recovered.

After nitrogen was introduced into the first reactor and the internal pressure was temporarily restored to the atmospheric pressure, the oligomerized reaction liquid in the first reactor was transferred into the second reactor. Increase in the temperature and decrease in the pressure in the second reactor were initiated, and an internal temperature of 240° C. and a pressure of 0.2 kPa were achieved in 50 minutes. The polymerization was then allowed to proceed until predetermined stirring power was achieved. At the point when the predetermined power was achieved, nitrogen was introduced into the reactor so that the pressure was restored to the original value, and the reaction liquid was extracted in the form of a strand and pelletized by using a rotary cutter. A polycarbonate resin A having a copolymer composition of BHEPF/ISB/DEG=43.8/53.7/2.5 [mol %] was thus obtained. The reduced viscosity of the polycarbonate resin was 0.430 dL/g, and the glass transition temperature thereof was 145° C.

After the resultant polycarbonate resin was dried in a vacuum at 80° C. for 5 hours, a film forming apparatus including a uniaxial extruder (manufactured by ISUZU KAKOUKI K.K., screw diameter: 25 mm, cylinder setting temperature: 240° C.), a T die (width: 900 mm, setting temperature: 240° C.), a chill roll (setting temperature: 120 to 130° C.), and a winder was used to produce a polycarbonate resin film having a thickness of 150 μm.

A sample having a width of 250 mm and a length of 250 mm was cut off from the polycarbonate resin film produced as described above. The sample was caused to undergo fixed-end uniaxial lateral stretching by using a batch-type biaxial stretcher (product name “KARO-IV” manufactured by Bruckner GmBH) at a stretching temperature of 145.6° C. and a stretching magnification of 2.4 to produce a retardation membrane having a thickness of 70 μm.

### Polarizing Film

An elongated polyvinyl alcohol film was sequentially immersed in the following five baths [1] to [5] with the film inserted between a plurality of sets of roll having different circumferential speeds so that tensile force acts in the longitudinal direction of the film, whereby the film was so stretched that the final stretching magnification was 6.0 with respect to the original length of the film. The film was dried for 4 minutes in an oven heated to 50° C., and a polarizing film having a thickness of 12 μm was produced.
[1] Swelling bath: Pure water at 30° C.
[2] Dyeing bath: With respect to 100 weight parts of water, iodine concentration was set at a value ranging from 0.02 to 0.2 wt %, and a potassium iodide concentration was set at a value ranging from 0.14 to 1.4 wt %. The concentration ratio between iodine and potassium iodide was 1:7. The film was so immersed in an aqueous solution containing the iodine and the potassium iodide and heated to 30° C. for an arbitrary period that the final transmittance of the polarizing film alone ranges from 41 to 47%.
[3] First crosslinking bath: Aqueous solution containing 3 wt % of potassium iodide and 3 wt % of boric acid and heated to 40° C.
[4] Second crosslinking bath: Aqueous solution containing 5 wt % of potassium iodide and 4 wt % of boric acid and heated to 60° C.
[5] Washing bath: Aqueous solution containing 3 wt % of potassium iodide and heated to 25° C.

### Polarizing Function Laminate

A film that is a hard-coated protective film made of triacetylcellulose and having undergone a hard coating treatment (product name “KC2UA” manufactured by KONICA MINOLTA JAPAN, INC., thickness: 25 μm) and a protective film made of triacetylcellulose and having undergone no surface treatment (product name “KC2UA” manufactured by KONICA MINOLTA JAPAN, INC., thickness: 25 μm) were prepared. The polarizing film and the retardation film produced as described above were each so cut as to have a size of 150 mm×300 mm. The retardation film was further so cut that the slow axis thereof inclined with respect to the short sides or the long sides thereof by 45°. The two protective films described above were bonded to the opposite surfaces of the polarizing film via a polyvinyl-alcohol-based adhesive. Further, the retardation film was bonded onto the laminate in which the protective films were bonded to the opposite surfaces of the polarizing film, specifically, onto the protective film having undergone no surface treatment via an acrylic adhesive layer in such a way that the slow axis of the retardation film inclines with respect to the absorption axis of the polarizing film by 45°. The produced polarizing function laminate was so trimmed as to have a size of 70 mm×120 mm to produce a polarizing function laminate that functions as a circularly polarizing plate.

### Optical Unit

A transparent electrically conductive film having the size of 70 mm×120 mm was cut off from the elongated transparent electrically conductive film produced as described above. In this process, the transparent electrically conductive film was so cut that the center thereof approximately coincides with the widthwise center of the elongated transparent electrically conductive film and the longitudinal direction thereof is parallel to the MD direction of the elongated transparent electrically conductive film. The transparent electrically-conductive-layer-side surface of the transparent electrically conductive film cut as described above was bonded to the retardation-membrane-side surface of the polarizing function laminate produced as described above via the acrylic adhesive layer in such a way that the direction of the slow axis of the retardation membrane was parallel to the MD direction of the transparent electrically conductive film. The optical unit was thus produced.

A variety of types of evaluation were performed on the resultant base material laminate having undergone the heating/winding process, retardation membrane, and optical unit, as will be described below. Table 1 shows the characteristics of the resultant base material laminate having undergone the heating/winding process, retardation membrane, and optical unit.

### Example A2

A base material laminate, a retardation membrane, and an optical unit were manufactured and produced under the same conditions as those in Example A1 except that the transparent electrically conductive film was so cut that the center thereof was separate by about 50 mm from a widthwise end of the elongated transparent electrically conductive film, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example A3

A base material laminate, a retardation membrane, and an optical unit were manufactured and produced under the same conditions as those in Example A1 except that the heating/winding process was carried out at a temperature of 140° C. and the retardation membrane stretching temperature was set at 145.4° C. so that a retardation membrane providing a different in-plane retardation was produced, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example A4

A base material laminate, a retardation membrane, and an optical unit were manufactured and produced under the same conditions as those in Example A3 except that the transparent electrically conductive film was so cut that the center thereof was separate by about 50 mm from a widthwise end of the elongated transparent electrically conductive film, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example A5

A base material laminate, a retardation membrane, and an optical unit were manufactured and produced under the same conditions as those in Example A1 except that the heating/winding process was carried out at a temperature of 145° C. and the retardation membrane stretching temperature was set at 145.4° C. so that a retardation membrane providing a different in-plane retardation was produced, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example A6

A base material laminate, a retardation membrane, and an optical unit were manufactured and produced under the same conditions as those in Example A5 except that the transparent electrically conductive film was so cut that the center thereof was separate by about 50 mm from a widthwise end of the elongated transparent electrically conductive film, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example A7

A base material laminate, a retardation membrane, and an optical unit were manufactured and produced under the same conditions as those in Example A1 except that the heating/winding process was carried out at a temperature of 155° C., and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example A8

A base material laminate, a retardation membrane, and an optical unit were manufactured and produced under the same conditions as those in Example A7 except that the transparent electrically conductive film was so cut that the center thereof was separate by about 50 mm from a widthwise end of the elongated transparent electrically conductive film, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example A9

A base material laminate, a retardation membrane, and an optical unit were manufactured and produced under the same conditions as those in Example A1 except that the transparent electrically conductive film was so cut that the center thereof was separate by about 100 mm from a widthwise end of the elongated transparent electrically conductive film, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example A10

A base material laminate, a retardation membrane, and an optical unit were manufactured and produced under the same conditions as those in Example A1 except that when the optical unit was produced, the transparent electrically conductive film and the polarizing function laminate were so bonded to each other that the direction of the slow axis of the retardation membrane inclines by 3° with respect to the MD direction of the transparent electrically conductive film, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example A11

A base material laminate, a retardation membrane, and an optical unit were manufactured and produced under the same conditions as those in Example A10 except that the transparent electrically conductive film was so cut that the center thereof was separate by about 50 mm from a widthwise end of the elongated transparent electrically conductive film, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example A12

A base material laminate, a retardation membrane, and an optical unit were manufactured and produced under the same conditions as those in Example A1 except that when the optical unit was produced, the transparent electrically conductive film and the polarizing function laminate were so bonded to each other that the direction of the slow axis of the retardation membrane inclines by 90° with respect to the MD direction of the transparent electrically conductive film, and that the retardation membrane stretching temperature was set at 146.1° C. so that a retardation membrane providing a different in-plane retardation was produced, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example A13

A base material laminate, a retardation membrane, and an optical unit were manufactured and produced under the same conditions as those in Example A12 except that the transparent electrically conductive film was so cut that the center thereof was separate by about 50 mm from a widthwise end of the elongated transparent electrically conductive film, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example B1

A base material laminate, a retardation membrane, and an optical unit were manufactured and produced under the same conditions as those in Example A1 except that as the elongated polycycloolefin film used to manufacture the transparent electrically conductive film, a polycycloolefin film in a lot different from the lot in Example A1 was used, and that the retardation membrane stretching temperature was set at 146.1° C. so that a retardation membrane providing a different in-plane retardation was produced, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example B2

A base material laminate, a retardation membrane, and an optical unit were manufactured and produced under the same conditions as those in Example B1 except that the transparent electrically conductive film was so cut that the center thereof was separate by about 50 mm from a widthwise end of the elongated transparent electrically conductive film, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example B3

A base material laminate, a retardation membrane, and an optical unit were manufactured and produced under the same conditions as those in Example B1 except that the heating/winding process was carried out at the temperature of 140° C., and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example B4

A base material laminate, a retardation membrane, and an optical unit were manufactured and produced under the same conditions as those in Example B3 except that the transparent electrically conductive film was so cut that the center thereof was separate by about 50 mm from a widthwise end of the elongated transparent electrically conductive film, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Example C

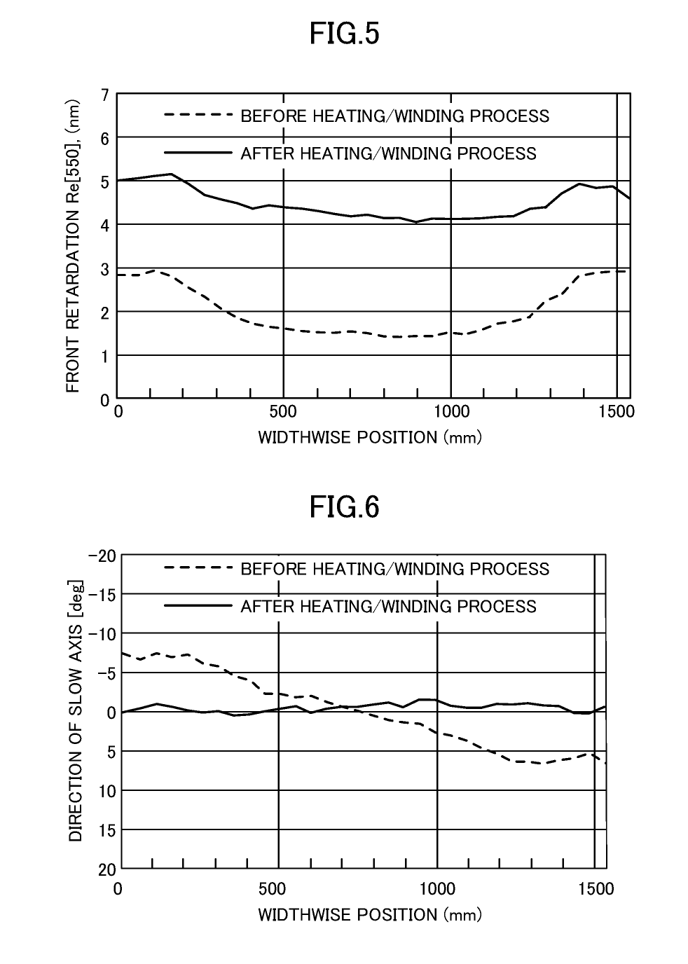

A base material laminate was manufactured and heated/wound under the same conditions as those in Example A1 except that as the elongated polycycloolefin film used to manufacture the base material laminate, a polycycloolefin film in a lot different from the lots in Examples A1 and B1 was used, and the variety of types of evaluation were performed on the base material laminate before and after the heating/winding process, as will be described below. FIGS. 5 and 6 show the characteristics of the base material laminate before and after the heating/winding process.

### Comparative Example A1

A transparent electrically conductive film, a retardation membrane, and an optical unit were manufactured and produced under the same conditions as those in Example A1 except that no heating/winding process was carried out and the retardation membrane was stretched at a temperature of 145.0° C., and the variety of types of evaluation were performed on the transparent electrically conductive film, the retardation membrane, and the optical unit, as will be described below. Table 1 shows the characteristics of the resultant base material laminate, retardation membrane, and optical unit.

### Comparative Example A2

A base material laminate, a retardation membrane, and an optical unit were manufactured and produced under the same conditions as those in Comparative Example A1 except that the transparent electrically conductive film was so cut that the center thereof was separate by about 50 mm from a widthwise end of the elongated transparent electrically conductive film, and the variety of types of evaluation were performed on the base material laminate, the retardation membrane, and the optical unit, as will be described below. Table 1 shows the characteristics of the resultant base material laminate, retardation membrane, and optical unit.

### Comparative Example A3

A base material laminate, a retardation membrane, and an optical unit were manufactured and produced under the same conditions as those in Comparative Example A1 except that the heating/winding process was carried out at a temperature of 130° C., and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Comparative Example A4

A base material laminate, a retardation membrane, and an optical unit were manufactured and produced under the same conditions as those in Comparative Example A3 except that the transparent electrically conductive film was so cut that the center thereof was separate by about 50 mm from a widthwise end of the elongated transparent electrically conductive film, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Comparative Example A5

A base material laminate, a retardation membrane, and an optical unit were manufactured and produced under the same conditions as those in Example A1 except that when the optical unit was produced, the transparent electrically conductive film and the polarizing function laminate were so bonded to each other that the direction of the slow axis of the retardation membrane inclines by 5° with respect to the MD direction of the transparent electrically conductive film, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Comparative Example A6

A base material laminate, a retardation membrane, and an optical unit were manufactured and produced under the same conditions as those in Comparative Example A5 except that the transparent electrically conductive film was so cut that the center thereof was separate by about 50 mm from a widthwise end of the elongated transparent electrically conductive film, and the variety of types of evaluation were performed on the base material laminate, the retardation membrane, and the optical unit, as will be described below. Table 1 shows the characteristics of the resultant base material laminate having undergone the heating/winding process, retardation membrane, and optical unit.

### Comparative Example B1

A transparent electrically conductive film, a retardation membrane, and an optical unit were manufactured and produced under the same conditions as those in Example B1 except that no heating/winding process was carried out and the retardation membrane was stretched at the temperature of 145.0° C., and the variety of types of evaluation were performed on the transparent electrically conductive film, the retardation membrane, and the optical unit, as will be described below. Table 1 shows the characteristics of the resultant base material laminate, retardation membrane, and optical unit.

### Comparative Example B2

A functional laminate, a retardation membrane, and an optical unit were manufactured and produced under the same conditions as those in Comparative Example B1 except that the transparent electrically conductive film was so cut that the center thereof was separate by about 50 mm from a widthwise end of the elongated transparent electrically conductive film, and the variety of types of evaluation were performed on the functional laminate, the retardation membrane, and the optical unit, as will be described below. Table 1 shows the characteristics of the resultant base material laminate, retardation membrane, and optical unit.

### Comparative Example B3

A functional laminate, a retardation membrane, and an optical unit were manufactured and produced under the same conditions as those in Comparative Example B1 except that the heating/winding process was carried out at the temperature of 150° C., as in Examples B1 and B2, and the variety of types of evaluation were performed on the functional laminate, the retardation membrane, and the optical unit, as will be described below. Table 1 shows the characteristics of the resultant base material laminate having undergone the heating/winding process, retardation membrane, and optical unit.

### Comparative Example B4

A functional laminate, a retardation membrane, and an optical unit were manufactured and produced under the same conditions as those in Examples B1 to B4 except that the heating/winding process was carried out at the temperature of 130° C., and the variety of types of evaluation were performed on the functional laminate, the retardation membrane, and the optical unit, as will be described below. Table 1 shows the characteristics of the resultant base material laminate having undergone the heating/winding process, retardation membrane, and optical unit.

### Comparative Example B5

A functional laminate, a retardation membrane, and an optical unit were manufactured and produced under the same conditions as those in Comparative Example B4 except that the transparent electrically conductive film was so cut that the center thereof was separate by about 50 mm from a widthwise end of the elongated transparent electrically conductive film, and the variety of types of evaluation were performed on the functional laminate, the retardation membrane, and the optical unit, as will be described below. Table 1 shows the characteristics of the resultant base material laminate, retardation membrane, and optical unit.

### Comparative Example B6

A functional laminate, a retardation membrane, and an optical unit were manufactured and produced under the same conditions as those in Comparative Example B1 except that the heating/winding process was carried out at a temperature of 165° C. and the retardation membrane stretching temperature was set at 146.4° C. so that a retardation membrane having a different in-plane retardation was produced, and the variety of types of evaluation were performed on the functional laminate, the retardation membrane, and the optical unit, as will be described below. Table 1 shows the characteristics of the resultant base material laminate having undergone the heating/winding process, retardation membrane, and optical unit.

### Comparative Example B7

A functional laminate, a retardation membrane, and an optical unit were manufactured and produced under the same conditions as those in Comparative Example B6 except that the transparent electrically conductive film was so cut that the center thereof was separate by about 50 mm from a widthwise end of the elongated transparent electrically conductive film, and the variety of types of evaluation were performed on the functional laminate, the retardation membrane, and the optical unit, as will be described below. Table 1 shows the characteristics of the resultant base material laminates, retardation membrane, and optical unit.

TABLE 1

| | | | | | | | | | Characteristics of optical unit | | | |
|---|---|---|---|---|---|---|---|---|---|---|---|---|
| | | | | | | | | | Angle | | | |
| | | | | | | | | | between | | | |
| | | | | | | | | | slow axis of | | | |
| | Heating/winding | | | | | | | | retardation | | | |
| | process conditions | | Characteristics of base material | | | Characteristics of retardation | | | membrane | | | |
| | Heating/winding | Heating/winding | laminate (polycycloolefin film) | | | membrane | | | and slow | | | |
| | process | process | | Re | Direction | Stretching | | Re | axis of base | | | |
| | temperature | period | Measurement | [550] | of slow | temperature | Stretching | [550] | material | Hue of reflected light | | Reflectance |
| | (° C.) | (min) | position | (nm) | axis (°) | (° C.) | magnification | (nm) | laminate (°) | a* | b* | (%) |
| Example A1 | 150 | 3 | Central | 4.1 | 0.0 | 145.6 | 2.4 | 139.1 | 0 | −0.50 | −2.04 | 5.28 |
| | | | portion | | | | | | | | | |
| Example A2 | 150 | 3 | End portion | 4.9 | 0.5 | 145.6 | 2.4 | 138.9 | 0 | −0.36 | −2.04 | 5.34 |
| Example A3 | 140 | 3 | Central | 3.4 | 0.1 | 145.4 | 2.4 | 140.0 | 0 | −0.61 | −2.11 | 5.31 |
| | | | portion | | | | | | | | | |
| Example A4 | 140 | 3 | End portion | 3.6 | 0.8 | 145.4 | 2.4 | 140.1 | 0 | −0.81 | −2.55 | 5.40 |
| Example A5 | 145 | 3 | Central | 3.7 | 0.1 | 145.4 | 2.4 | 140.1 | 0 | −0.52 | −2.09 | 5.33 |
| | | | portion | | | | | | | | | |
| Example A6 | 145 | 3 | End portion | 4.2 | 0.8 | 145.6 | 2.4 | 139.1 | 0 | −0.49 | −2.19 | 5.36 |
| Example A7 | 155 | 3 | Central | 4.1 | 0 | 145.6 | 2.4 | 139.1 | 0 | −0.58 | −2.12 | 5.29 |
| | | | portion | | | | | | | | | |
| Example A8 | 155 | 3 | End portion | 4.9 | 0.5 | 145.6 | 2.4 | 138.9 | 0 | −0.63 | −2.15 | 5.38 |
| Example A9 | 150 | 3 | Position | 4.2 | 1.8 | 145.6 | 2.4 | 139.1 | 0 | −0.75 | −2.49 | 5.43 |
| | | | separate | | | | | | | | | |
| | | | from end | | | | | | | | | |
| | | | portion by | | | | | | | | | |
| | | | about 100 | | | | | | | | | |
| | | | mm | | | | | | | | | |
| Example A10 | 150 | 3 | Central | 4.1 | 0 | 145.6 | 2.4 | 139.0 | 3 | −0.95 | −2.45 | 5.81 |
| | | | portion | | | | | | | | | |
| Example A11 | 150 | 3 | End portion | 4.9 | 0.5 | 145.6 | 2.4 | 139.1 | 3.5 | −1.08 | −2.78 | 5.89 |
| Example A12 | 150 | 3 | Central | 4.1 | 0 | 144.4 | 2.4 | 147.2 | 90 | −0.42 | −1.81 | 5.24 |
| | | | portion | | | | | | | | | |
| Example A13 | 150 | 3 | End portion | 4.9 | 0.5 | 144.4 | 2.4 | 147.2 | 90 | −0.53 | −1.99 | 5.33 |
| Example B1 | 150 | 3 | Central | 6.8 | 0.1 | 146.1 | 2.4 | 135.1 | 0 | −0.57 | −2.05 | 5.29 |
| | | | portion | | | | | | | | | |
| Example B2 | 150 | 3 | End portion | 7.4 | 0.5 | 146.1 | 2.4 | 135.0 | 0 | −0.80 | −2.31 | 5.36 |
| Example B3 | 140 | 3 | Central | 6.5 | 0.1 | 146.1 | 2.4 | 135.0 | 0 | −0.52 | −2.23 | 5.42 |
| | | | portion | | | | | | | | | |
| Example B4 | 140 | 3 | End portion | 7.1 | 0.5 | 146.1 | 2.4 | 135.1 | 0 | −0.59 | −2.43 | 5.48 |
| Comparative | No | — | Central | 1.3 | 0.1 | 145.0 | 2.4 | 143.0 | 0 | −0.75 | −2.39 | 5.32 |
| Example A1 | process | | portion | | | | | | | | | |
| Comparative | No | — | End portion | 2.9 | 6.4 | 145.0 | 2.4 | 143.1 | 0 | −1.88 | −3.01 | 5.44 |
| Example A2 | process | | | | | | | | | | | |
| Comparative | 130 | 3 | Central | 2.3 | 0.2 | 145.0 | 2.4 | 143.1 | 0 | −0.59 | −2.07 | 5.33 |
| Example A3 | | | portion | | | | | | | | | |
| Comparative | 130 | 3 | End portion | 2.6 | 2.7 | 145.0 | 2.4 | 143.0 | 0 | −1.01 | −2.79 | 5.48 |
| Example A4 | | | | | | | | | | | | |
| Comparative | 150 | 3 | Central | 4.1 | 0 | 145.6 | 2.4 | 139.0 | 5 | −1.23 | −2.99 | 6.41 |
| Example A5 | | | portion | | | | | | | | | |
| Comparative | 150 | 3 | End portion | 4.9 | 0.5 | 145.6 | 2.4 | 139.1 | 5.5 | −1.41 | −3.12 | 6.49 |
| Example A6 | | | | | | | | | | | | |
| Comparative | No | — | Central | 2.1 | 0.2 | 145.0 | 2.4 | 143.0 | 0 | −0.61 | −2.10 | 5.31 |
| Example B1 | process | | portion | | | | | | | | | |
| Comparative | No | — | End portion | 3.4 | 7.2 | 145.0 | 2.4 | 143.0 | 0 | −1.93 | −3.21 | 5.51 |
| Example B2 | process | | | | | | | | | | | |
| Comparative | 150 | 3 | Central | 6.8 | 0.1 | 145.0 | 2.4 | 143.0 | 0 | −1.77 | −2.99 | 5.50 |
| Example B3 | | | portion | | | | | | | | | |
| Comparative | 130 | 3 | Central | 5.6 | 0.2 | 146.1 | 2.4 | 135.0 | 0 | −0.61 | −2.34 | 5.35 |
| Example B4 | | | portion | | | | | | | | | |
| Comparative | 130 | 3 | End portion | 6.7 | 2.9 | 146.1 | 2.4 | 135.0 | 0 | −0.95 | −2.67 | 5.77 |
| Example B5 | | | | | | | | | | | | |
| Comparative | 165 | 3 | Central | 9.5 | 0.1 | 146.4 | 2.4 | 133.1 | 0 | −0.85 | −2.45 | 5.38 |
| Example B6 | | | portion | | | | | | | | | |
| Comparative | 165 | 3 | End portion | 10.2 | 0.7 | 146.4 | 2.4 | 133.4 | 0 | −0.88 | −2.54 | 5.47 |
| Example B7 | | | | | | | | | | | | |

### Evaluation

### (Measurement of Thickness)

The thicknesses of the polarizing film, the retardation membrane, and the protective membrane were measured with a dial gauge (manufactured by Mitsutoyo Corporation).

### (Measurement of In-Plane Retardation and Direction of Slow Axis)

The in-plane retardation and the direction of the slow axis of the base material laminate and the in-plane retardation of the retardation membrane were measured indoors at 23° C. with [product name “AxoScan” manufactured by Axometrics, Inc.]. In the measurement of the in-plane retardation and the direction of the slow axis of the resultant base material laminate, since the influence of the first and second curable resin layers and the optical adjustment layer in the base material laminate can be ignored, the measured in-plane retardation and direction of the slow axis of the base material laminate can be considered as the in-plane retardation and the direction of the slow axis of the polycycloolefin film. The sample of each of the base material laminates in Examples A1 to A4 and B1 to B2 and Comparative Examples A1 to A4 and B1 to B3 was produced as follows: A sample having the size of 70 mm×120 mm was cut off from the resultant elongated base material laminate in such a way that the widthwise center of the cut base material laminate is located at the center of the elongated base material laminate or in the position separate by 50 mm from a widthwise end thereof and the longitudinal direction thereof is parallel to the MD direction. The direction of the slow axis of the base material laminate was measured in the form of the angle with respect to the longitudinal direction, that is, the MD direction of the sample. In the case of the base material laminate in Example C, the base material laminate out of the roll of the resultant base material laminate before the heating/winding process and the base material laminate out of the roll of the resultant base material laminate after the heating/winding process were not cut, and the in-plane retardation and the direction of the slow axis of were measured at 50-nm intervals from the widthwise end of each of the base material laminates.

### (Measurement of Reflectance and Hue of Optical Unit)

A reflector which was made of PET and on which aluminum was vapor-deposited (product name “Cerapeel DMS-X42” manufactured by TORAY ADVANCED FILM CO., LTD.) was bonded to the transparent electrically conductive film of the resultant optical unit with an acrylic adhesive (thickness: 23 μm) to form a sample for the measurement. The reflectance of the surface of the polarizing film of the optical unit was measured in the vicinity of the center of the surface, and the hue of light (a*, b*) reflected off the surface was measured in the vicinity of the center of the surface. The measurement was performed indoors at 23° C. in the form of a reflected light spectrum with a spectral colorimeter [product name “CM-2600d” manufactured by Konica Minolta Sensing, Inc.]. As a light source, the value at D65 was used, and the measurement was performed in accordance with an SCI (specular component included) method (including specularly reflected light).

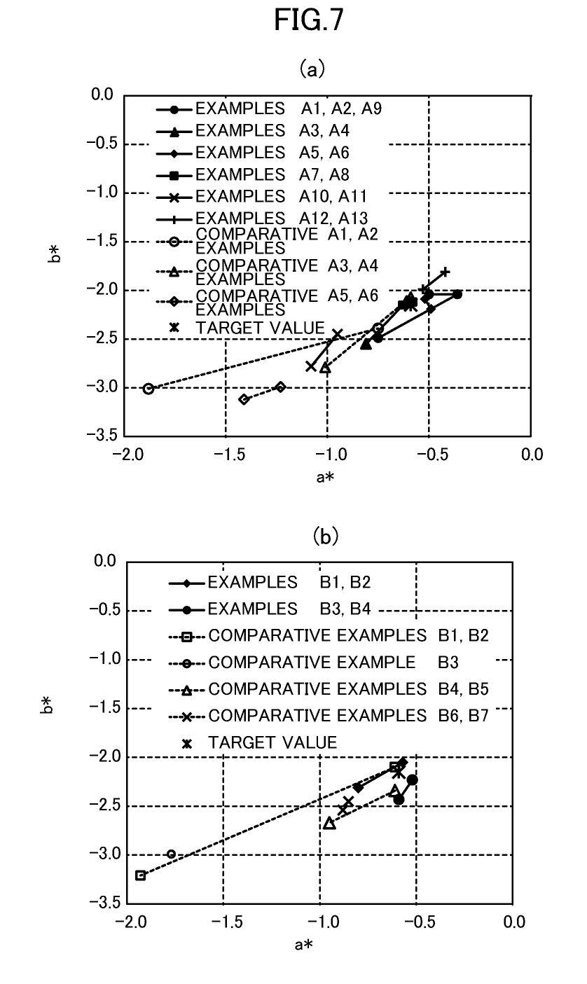

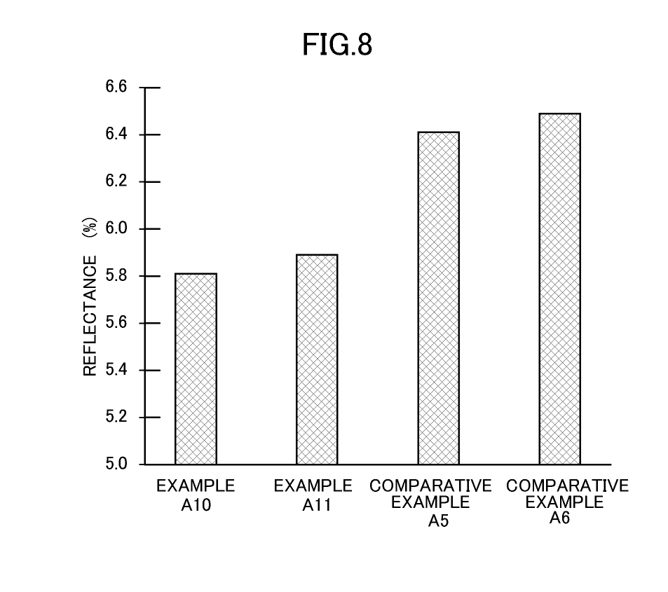

Table 1 shows results of the measurement. FIGS. 5 and 6 show changes in the direction of the slow axis and the retardation before and after the heating/winding process versus the position in the width direction of the polycycloolefin film in Example C. As described above, in the measurement of the in-plane retardation and the direction of the slow axis of the resultant base material laminate, since the influence of the first and second curable resin layers and the optical adjustment layer in the base material laminate can be ignored, the measured in-plane retardation and direction of the slow axis of the base material laminate can be considered as the in-plane retardation and the direction of the slow axis of the polycycloolefin film. FIGS. 7(a) and 7(b) show results of the measurement of the hue of the reflected light in Examples A1 to A13, Comparative Examples A1 to A6, Examples B1 to B4, and Comparative Examples B1 to B7. In FIGS. 7(a) and 7(b), the reflected light hue (a*, b*)=(−0.59, −2.15) of a retardation membrane alone used in Comparative Example is shown as a target value. FIG. 8 shows results of the measurement of the reflectance in Examples A10, A11 and Comparative Example A5, A6.

### (Evaluation)

the following points were found from FIG. 5: The in-plane retardation increases with distance from the central portion toward the end portions of the polycycloolefin film in the width direction thereof before the heating/winding process. The minimum in-plane retardation was 1.30 nm, and the maximum in-plane retardation was 2.86 nm. In contrast, in the polycycloolefin film after the heating/winding process, the minimum in-plane retardation is 3.99 nm, and the maximum in-plane retardation was 5.11 nm, indicating that the in-plane retardation increased across the width of the film, but that the variation in the in-plane retardation value was reduced from 1.55 nm, which was the value before the heating/winding process, to 1.12 nm.

Further, the direction of the slow axis was parallel to the MD direction in the widthwise central portion of the polycycloolefin film before the heating/winding process, but the discrepancy of the direction of the slow axis from the MD direction increased with distance from the central portion toward the end portions in the width direction. Inclination of the direction of the slow axis with respect to the MD direction fell within an angular range from −7.27° to +7.08°, which was significantly greater than the angular range of±2°. In contrast, the polycycloolefin film after the heating/winding process showed that inclination of the direction of the slow axis with respect to the MD direction fell within an angular range from −1.26° to +0.67° or fell within an angular range of±1.5° with respect to the MD direction. That is, the heating/winding process allowed the direction of the slow axis of the polycycloolefin film to be aligned with the MD direction, whereby the variation in the direction of the slow axis could be suppressed.

The following points were found from Table 1: In Examples A1 to A9 and B1 to B4, inclination of the direction of the slow axis of the polycycloolefin film with respect to the MD direction of the transparent electrically conductive film fell within the range of±2°, indicating that the direction of the slow axis was approximately aligned with the MD direction. In Comparative Examples A2, A4, B2, and B5, in each of which the end portion of the transparent electrically conductive film was cut, however, inclination of the direction of the slow axis of the polycycloolefin film with respect to the MD direction of the transparent electrically conductive film was greater than or equal to 2.7°, indicating that inclination of the direction of the slow axis was greater than the angular range of±2°. That is, the direction of the slow axis of the polycycloolefin film in each of Examples could be aligned with the MD direction, and the variation in the direction of the slow axis could be suppressed.

Examples A2, A4, A6, and A8, Comparative Example A4, Examples B2 and B4, and Comparative Example B5 showed that the direction of the slow axis approached the MD direction and the variation in the direction of the slow axis was suppressed as the temperature in the heating/winding process approaches 165° C., which was the glass transition temperature (Tg) of the polycycloolefin film.

In Comparative Examples B6 and B7, the in-plane retardation of the polycycloolefin film was greater than or equal to 9.5 nm. That is, when the temperature in the heating/winding process reached 165° C., which is Tg of the polycycloolefin film, the in-plane retardation of the polycycloolefin film exceeded 8 nm.

Therefore, since in Examples A1 to A9 and B1 to B4, the temperature in the heating/winding process ranged from 140 to 155° C., in Comparative Examples A4 and B5, the temperature was 130° C., and in Comparative Examples B6 and B7, the temperature was 165° C., it was found that the temperature in the heating/winding process preferably ranged from 140 to 160° C., more preferably from 145 to 155° C., further preferably from 148 to 153° C.

The in-plane retardation of the polycycloolefin film in Examples A1 to A9 and B1 to B4 was greater than the in-plane retardation of the elongated polycycloolefin film having undergone no heating/winding process in Comparative Examples A1 to A4 and B1 to B2, but in each of Examples A1, A2, and A9, Examples A3 and A4, Examples A5 and A6, Examples A7 and A8, Examples B1 and B2, and Examples B3 and B4, the variation in the in-plane retardation of the elongated polycycloolefin film fell within a range of 1 nm, indicating that the in-plane retardation was approximately constant irrespective of the position in the polycycloolefin film.

As seen from FIGS. 7(a) and 7(b), the reflected light hue in Examples A1 to A9, A12 to A13, and B1 to B4 was close to the target reflected light hue, and the reflected light hue in Examples A2, A4, and A9 and Example B2 was closer to the target reflected light hue than the reflected light hue in Comparative Examples A2 and A4 and Comparative Examples B2, B5, and B7. Further, the reflected light hue in Examples B1 to B4 was closer to the target reflected light hue than the reflected light hue in Comparative Example B3.

That is, in each of the optical units in Examples, the heating/winding process increased the in-plane retardation of the polycycloolefin film, but the direction of the slow axis of the polycycloolefin film was aligned with the MD direction, and the in-plane retardation was approximately constant irrespective of the position in the polycycloolefin film. Since the in-plane retardation of the retardation membrane canceled the little-varying, approximately constant in-plane retardation of the polycycloolefin film so that the retardation membrane and the transparent electrically conductive film as a whole had in-plane retardation of about a quarter of the wavelength, the hue of light reflected off the optical unit had a satisfactory value.

Taking into account the fact that incidence of light through the air on a polarizing film itself caused reflection at the surface of the polarizing film corresponding to approximately 5% reflectance, as understood from FIG. 8, the reflectance of the optical units in Examples A10 and A11, in which the direction of the slow axis of the retardation membrane with respect to the MD direction of the transparent electrically conductive film was 3° (the direction of the slow axis of the retardation membrane with respect to the slow axis of the polycycloolefin film is 3°, 3.5°), was greatly smaller than the reflectance in Comparative Examples A5 and A6, in which the direction of the slow axis of the retardation membrane with respect to the MD direction of the transparent electrically conductive film was 5° (the direction of the slow axis of the retardation membrane with respect to the slow axis of the polycycloolefin film is 5°, 5.5°). Since the reflectance in Examples A1 to A9, A12 to A13, and B1 to B4, in which the direction of the slow axis of the retardation membrane with respect to the MD direction of the transparent electrically conductive film was 0° or 90°, was smaller than the reflectance in Examples A10 and A11, the reflectance could be suppressed in each of the optical units in Examples.

The specific embodiment of the present invention has been described above with reference to the drawings. In the present invention, many changes can be made to the illustrated and described configuration. The present invention is therefore not limited to the illustrated and described configuration, and the scope of the present invention should be specified only by the accompanied claims and an equivalent range thereof.

### REFERENCE SIGNS LIST

1 Base material laminate
10 Polycycloolefin film
11 First curable resin layer
12 Second curable resin layer
12a Protrusion (on surface of second curable resin layer)
13 Transparent electrically conductive layer
14 Spherical particle
16 Optical adjustment layer
S1 First principal surface (of polycycloolefin film)
S2 Second principal surface (of polycycloolefin film)
w Most frequent particle diameter of spherical particle
d Thickness of binder resin layer
100 Organic EL display device
101 Organic EL display panel
102 Window
110 Optical unit
112 Transparent electrically conductive layer
115 Polycycloolefin film
116 Transparent electrically conductive film
120 Polarizing function laminate
121 Polarizing film
123 Retardation film
900 Organic EL display device
901 Organic EL display panel
912-1, 912-2 Patterned electrode
915 Dielectric layer
920 Polarizing function laminate
921 Polarizing film
923 Retardation layer

1. A laminate roll that is an elongated laminate wound in a form of a roll,
wherein the laminate includes a transparent electrically conductive film including a substantially unstretched polycycloolefin film and a transparent electrically conductive layer, and
inclination of a direction of a slow axis of the polycycloolefin film with respect to a longitudinal direction of the elongated laminate falls within a range of±2° over the entire elongated laminate except opposite end portions thereof each of which accounts for 5% of an entire width of the elongated laminate.

2. An optical unit comprising:
a transparent electrically conductive film including a substantially unstretched polycycloolefin film and a transparent electrically conductive layer; and
a retardation film,
wherein a direction of a slow axis of the polycycloolefin film has an angular variation that falls within a range of 4°,
in-plane retardation of the polycycloolefin film measured by using light having a wavelength of 550 nm at 23° C. ranges from 3 to 8 nm, and variation in the in-plane retardation falls within a range of 1.5 nm, and
in-plane retardation of the retardation film is so set as to cancel the in-plane retardation of the polycycloolefin film so that the retardation film and the transparent electrically conductive film as a whole have a desired in-plane retardation value.

3. The optical unit according to claim 2, wherein the retardation film includes a quarter-wave retardation membrane, and the desired value is about a quarter of the wavelength.

4. The optical unit according to claim 2, wherein the retardation film includes a retardation membrane for angular viewing field compensation and a quarter-wave retardation membrane sequentially arranged from a side facing the transparent electrically conductive film, and the desired value is about a quarter of the wavelength.

5. The optical unit according to claim 3, wherein inclination of a direction of a slow axis of the quarter-wave retardation membrane with respect to the direction of the slow axis of the polycycloolefin film falls within a range of 0°35 3°.

6. The optical unit according to claim 3, wherein inclination of a direction of a slow axis of the quarter-wave retardation membrane with respect to the direction of the slow axis of the polycycloolefin film falls within a range of 90°35 3°.

7. The optical unit according to claim 2, wherein the transparent electrically conductive layer is made of indium tin oxide (ITO).

8. The optical unit according to claim 2, wherein the optical unit further comprises a polarizing function laminate,
the polarizing function laminate includes a polarizing film and the retardation film,
the retardation film is disposed on a side facing the transparent electrically conductive layer of the transparent electrically conductive film, and
the polarizing film is disposed on a side opposite to the transparent electrically conductive film with respect to the retardation film.

9. The optical unit according to claim 8, wherein the polarizing function laminate has a function of producing circularly polarized light.

10. An organic EL display device comprising:
the optical unit according to claim 9; and
an organic EL display panel,
wherein the optical unit is disposed on a visually recognized side of the organic EL display panel, and
the optical unit is further so disposed that the transparent electrically conductive film is located between the polarizing film and the organic EL display panel.

11. A method for manufacturing a transparent electrically conductive film, the method comprising the steps of:
feeding a polycycloolefin film from a polycycloolefin film roll that is an elongated polycycloolefin film wound in a form of a roll;
carrying out a heating/winding process at a heating temperature ranging from 140 to 160° C. while winding the fed polycycloolefin film around a wind-up roll; and
depositing a transparent electrically conductive layer on the polycycloolefin film having undergone the heating/winding process to produce a transparent electrically conductive film,
wherein the polycycloolefin film is not stretched substantially.

12. The method for manufacturing a transparent electrically conductive film according to claim 11, wherein the heating temperature ranges from 145 to 155° C.

13. The method for manufacturing a transparent electrically conductive film according to claim 11, wherein the heating temperature ranges from 148 to 153° C.

14. A method for manufacturing the optical unit according to claim 8, wherein the polarizing function laminate is bonded to the transparent electrically conductive film manufactured by using the manufacturing method according to claim 11 to produce the optical unit.
